(19) United States
(12) Patent Application Publication
(10) Pub. No.: US 2025/0202509 A1
(43) Pub. Date: Jun. 19, 2025

(54) RADIO FREQUENCY CIRCUIT

(71) Applicant: Murata Manufacturing Co., Ltd., Nagaokakyo-shi (JP)

(72) Inventors: Hirotsugu MORI, Nagaokakyo-shi (JP); Morio TAKEUCHI, Nagaokakyo-shi (JP)

(73) Assignee: Murata Manufacturing Co., Ltd., Nagaokakyo-shi (JP)

(21) Appl. No.: 19/058,052

(22) Filed: Feb. 20, 2025

Related U.S. Application Data
(63) Continuation of application No. PCT/JP2023/020382, filed on May 31, 2023.

(30) Foreign Application Priority Data
Aug. 23, 2022 (JP) 2022-132852

(51) Int. Cl. H04B 1/00; H04B 1/04

(52) U.S. Cl. CPC H04B 1/0078; H04B 1/04; H04B 2001/0416

(57) ABSTRACT

A radio frequency circuit includes: a first filter having a passband that includes a transmission band of a first band to which power classes are applicable; a second filter having a passband that includes the transmission band of the first band; a first combiner that includes a first input terminal, a second input terminal, and an output terminal; and a first switch that includes a first terminal, a second terminal, a third terminal, a fourth terminal, and a fifth terminal. The output terminal of the first combiner is connected to an antenna connection terminal.

### CROSS-REFERENCE TO RELATED APPLICATIONS

This is a continuation application of PCT International Application No. PCT/JP2023/020382 filed on May 31, 2023, designating the United States of America, which is based on and claims priority to Japanese Patent Application No. 2022-132852 filed on Aug. 23, 2022. The entire disclosures of the above-identified applications, including the specifications, drawings and claims are incorporated herein by reference in their entirety.

### TECHNICAL FIELD

The present disclosure relates to a radio frequency circuit.

### BACKGROUND

The 3rd Generation Partnership Project (3GPP (registered trademark)) has been examining applying, to a specific band, a power class (such as Power Class 2, for example) that allows a maximum output power higher than that of a conventional class.

### SUMMARY

### Technical Problems

However, as recognized by the present inventor, it is difficult for a conventional radio frequency circuit as disclosed in U.S. Patent Application Publication No. 2015/0133067 to support a plurality of power classes.

In view of this, the present disclosure provides a radio frequency circuit that can support a plurality of power classes.

### Solutions

A radio frequency circuit according to an aspect of the present disclosure includes: a first filter having a passband that includes a transmission band of a first band to which a plurality of power classes are applicable; a second filter having a passband that includes the transmission band of the first band; a first combiner that includes a first input terminal, a second input terminal, and an output terminal; and a first switch that includes a first terminal, a second terminal, a third terminal, a fourth terminal, and a fifth terminal. The output terminal of the first combiner is connected to an antenna connection terminal. The first terminal of the first switch is connected to one end of the first filter. The second terminal of the first switch is connected to one end of the second filter. The third terminal of the first switch is connected to the first input terminal of the first combiner. The fourth terminal of the first switch is connected to the second input terminal of the first combiner, and the fifth terminal of the first switch is connected to the antenna connection terminal not via the first combiner.

### Advantageous Effects

According to the present disclosure, a plurality of power classes can be supported.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 illustrates a circuit configuration of a communication device according to Embodiment 1.

FIG. 2 illustrates a circuit configuration of a first example of a combiner according to Embodiment 1.

FIG. 3 illustrates a circuit configuration of a second example of the combiner according to Embodiment 1.

FIG. 4 illustrates a circuit configuration of a third example of the combiner according to Embodiment 1.

FIG. 5 illustrates transmission paths in a first mode of a radio frequency circuit according to Embodiment 1.

FIG. 6 illustrates a transmission path in a second mode of the radio frequency circuit according to Embodiment 1.

FIG. 7 illustrates a circuit configuration of a radio frequency circuit according to a variation of Embodiment 1.

FIG. 8 illustrates a circuit configuration of a radio frequency circuit according to Embodiment 2.

FIG. 9 illustrates a circuit configuration of a first example of a combiner according to Embodiment 2.

FIG. 10 illustrates a circuit configuration of a second example of the combiner according to Embodiment 2.

FIG. 11 illustrates a circuit configuration of a third example of the combiner according to Embodiment 2.

FIG. 12 illustrates transmission paths in a first mode of the radio frequency circuit according to Embodiment 2.

FIG. 13 illustrates transmission paths in a second mode of the radio frequency circuit according to Embodiment 2.

FIG. 14 illustrates transmission paths in a third mode of the radio frequency circuit according to Embodiment 2.

FIG. 15 illustrates a circuit configuration of a radio frequency circuit according to Embodiment 3.

FIG. 16 illustrates transmission paths in a first mode of the radio frequency circuit according to Embodiment 3.

FIG. 17 illustrates transmission paths in a second mode of the radio frequency circuit according to Embodiment 3.

FIG. 18 illustrates transmission paths in a third mode of the radio frequency circuit according to Embodiment 3.

FIG. 19 illustrates a circuit configuration of a radio frequency circuit according to Embodiment 4.

FIG. 20 illustrates transmission paths in a first mode of the radio frequency circuit according to Embodiment 4.

FIG. 21 illustrates transmission paths and reception paths in a second mode of the radio frequency circuit according to Embodiment 4.

FIG. 22 illustrates transmission paths and a reception path in a third mode of the radio frequency circuit according to Embodiment 4.

FIG. 23 illustrates transmission paths and a reception path in a fourth mode of the radio frequency circuit according to Embodiment 4.

FIG. 24 illustrates a circuit configuration of a radio frequency circuit according to Embodiment 5.

FIG. 25 illustrates transmission paths and reception paths in a first mode of the radio frequency circuit according to Embodiment 5.

FIG. 26 illustrates transmission paths and reception paths in a second mode of the radio frequency circuit according to Embodiment 5.

### DESCRIPTION OF EMBODIMENTS

The following describes in detail embodiments of the present disclosure with reference to the drawings. Note that the embodiments described below each show a general or specific example. The numerical values, shapes, materials, elements, and the arrangement and connection of the elements, for instance, described in the following embodiments are examples, and thus are not intended to limit the present disclosure.

Note that the drawings are schematic diagrams to which emphasis, omission and ratio adjustment are appropriately added in order to illustrate the present disclosure, and thus are not necessarily accurate illustrations. The drawings may show shapes, positional relations, and ratios that are different from actual shapes, actual positional relations, and actual ratios. Throughout the drawings, the same numeral is given to substantially the same element, and redundant description may be omitted or simplified.

In the circuit configurations according to the present disclosure, “being connected” includes not only the case of being directly connected by a connection terminal and/or a line conductor, but also the case of being electrically connected via another circuit element. “Being connected between A and B” means being connected between A and B and to both A and B, and means being disposed in series onto a path that connects A and B.

In the circuit configurations according to the present disclosure, a “terminal” means a point at which a conductor in an element ends. Note that under a condition that an impedance of a conductor between elements is sufficiently low, a terminal is interpreted not only as a single fixed point, but also as any point on the conductor between the elements or as the entire conductor.

### Embodiment 1

Embodiment 1 is to be described. Communication device 5 according to the present embodiment corresponds to a user equipment (UE) in a cellular network, and typically is a mobile phone, a smartphone, a tablet computer, or a wearable device, for instance. Note that communication device 5 may be an Internet of Things (IoT) sensor/device, a medical/health care device, a vehicle, an unmanned aerial vehicle (UAV) (a so-called drone), or an automated guided vehicle (AGV).

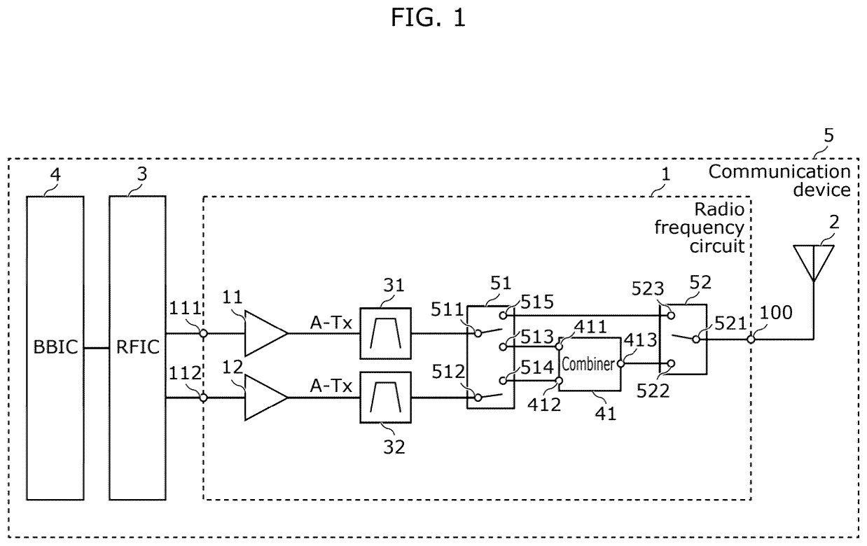

A circuit configuration of communication device 5 and radio frequency circuit 1 according to the present embodiment is to be described with reference to FIG. 1. FIG. 1 illustrates a circuit configuration of communication device 5 according to the present embodiment.

Note that FIG. 1 illustrates an exemplary circuit configuration, and communication device 5 and radio frequency circuit 1 may be and circuit technologies. Thus, the description of communication device 5 and radio frequency circuit 1 provided below should not be interpreted in a limited manner.

### [1.1 Circuit Configuration of Communication Device 5]

First, a circuit configuration of communication device 5 according to the present embodiment is to be described with reference to FIG. 1. Communication device 5 includes radio frequency circuit 1, antenna 2, radio frequency integrated circuit (RFIC) 3, and baseband integrated circuit (BBIC) 4.

Radio frequency circuit 1 transfers radio frequency signals between antenna 2 and RFIC 3. A circuit configuration of radio frequency circuit 1 is to be described later.

Antenna 2 is connected to antenna connection terminal 100 of radio frequency circuit 1. Antenna 2 receives radio frequency signals from radio frequency circuit 1 and outputs the radio frequency signals to the outside of communication device 5. Antenna 2 may receive radio frequency signals from the outside of communication device 5 and output the radio frequency signals to radio frequency circuit 1. Note that antenna 2 may not be included in communication device 5. Communication device 5 may further include one or more antennas in addition to antenna 2.

RFIC 3 is an example of a signal processing circuit that processes radio frequency signals. Specifically, RFIC 3 processes transmission signals input from BBIC 4 by up-conversion, for instance, and outputs radio frequency transmission signals generated by processing the transmission signals to radio frequency circuit 1. Furthermore, RFIC 3 may process radio frequency received signals input through a reception path of radio frequency circuit 1 by down-conversion, for instance, and output received signals generated by processing the radio frequency received signals to BBIC 4. RFIC 3 includes a controller that controls, for instance, a switch and a power amplifier that are included in radio frequency circuit 1. Note that part of or the entire functionality of RFIC 3 as a controller may be provided outside RFIC 3, and thus may be provided in BBIC 4 or radio frequency circuit 1, for example.

BBIC 4 is a base band signal processing circuit that processes signals using an intermediate frequency band lower than a frequency of a radio frequency signal transferred by radio frequency circuit 1. The signals processed by BBIC 4 are used, for example, as image signals for image display and/or as audio signals for talk through a loudspeaker. Note that BBIC 4 may not be included in communication device 5. Note that BBIC 4 may not be included in communication device 5.

### [2.1 Circuit Configuration of Radio Frequency Circuit 1]

Next, a circuit configuration of radio frequency circuit 1 according to the present embodiment is to be described with reference to FIG. 1. Radio frequency circuit 1 includes power amplifiers 11 and 12, filters 31 and 32, combiner 41, switches 51 and 52, antenna connection terminal 100, and radio frequency input terminals 111 and 112.

Antenna connection terminal 100 is an external connection terminal of radio frequency circuit 1. Specifically, antenna connection terminal 100 is connected to antenna 2 outside radio frequency circuit 1 and is connected to filter 31 inside radio frequency circuit 1. Accordingly, radio frequency circuit 1 can supply antenna 2 with transmission signals via antenna connection terminal 100, and can receive signals received from antenna 2 via antenna connection terminal 100.

Radio frequency input terminals 111 and 112 are external connection terminals of radio frequency circuit 1. Specifically, input terminal 111 is connected to RFIC 3 outside radio frequency circuit 1 and is connected to power amplifier 11 inside radio frequency circuit 1. Radio frequency input terminal 112 is connected to RFIC 3 outside radio frequency circuit 1 and is connected to power amplifier 12 inside radio frequency circuit 1. Accordingly, radio frequency circuit 1 can receive radio frequency transmission signals from RFIC 3 via radio frequency input terminals 111 and 112.

Power amplifier 11 is an example of a first power amplifier. The input end of power amplifier 11 is connected to radio frequency input terminal 111. The output end of power amplifier 11 is connected to filter 31. Power amplifier 11 can amplify input signals (transmission signals in Band A in the present embodiment) from radio frequency input terminal 111, by using power supplied from a power source (not illustrated).

Power amplifier 12 is an example of a second power amplifier. The input end of power amplifier 12 is connected to radio frequency input terminal 112. The output end of power amplifier 12 is connected to filter 32. Power amplifier 12 can amplify input signals (transmission signals in Band A in the present embodiment) from radio frequency input terminal 112, by using power supplied from a power source (not illustrated).

Power amplifiers 11 and 12 can include heterojunction bipolar transistors (HBTs), and can be manufactured using a semiconductor material. As the semiconductor material, silicon-germanium (SiGe) or gallium arsenide (GaAs) can be used, for example. Note that amplifier transistors of power amplifiers 11 and 12 are not limited to HBTs. For example, at least one of power amplifier 11 or power amplifier 12 may include a high electron mobility transistor (HEMT) or a metal-semiconductor field effect transistor (MESFET). In this case, gallium nitride (GaN) or silicon carbide (SIC) may be used as the semiconductor material.

Note that at least one of power amplifier 11 or power amplifier 12 may not be included in radio frequency circuit 1. In this case, power amplifier 11 may be connected between RFIC 3 and radio frequency input terminal 111, and power amplifier 12 may be connected between RFIC 3 and radio frequency input terminal 112. At least one of power amplifier 11 or power amplifier 12 may be included in RFIC 3.

Filter 31 is an example of a first filter, and is connected between antenna connection terminal 100 and radio frequency input terminal 111. Specifically, one end of filter 31 is connected to switch 51, and another end of filter 31 is connected to the output end of power amplifier 11. Filter 31 is a bandpass filter having a passband that includes a transmission band of Band A. Note that filter 31 is not limited to a bandpass filter.

Filter 32 is an example of a second filter, and is connected between antenna connection terminal 100 and radio frequency input terminal 112. Specifically, one end of filter 32 is connected to switch 51, and another end of filter 32 is connected to the output end of power amplifier 12. Filter 32 is a bandpass filter having a passband that includes a transmission band of Band A. Note that filter 32 is not limited to a bandpass filter.

A surface acoustic wave (SAW) filter, a bulk acoustic wave (BAW) filter, an inductor-capacitor (LC) resonator filter, a dielectric resonator filter, or a combination of any of these may be used as each of such filters 31 and 32, and furthermore, filters 31 and 32 are not limited to these.

Band A is a frequency band for a communication system established by using radio access technology (RAT). Band A is defined in advance by, for instance, a standardizing body (such as the 3GPP or the Institute of Electrical and Electronics Engineers (IEEE), for example). Examples of the communication system include a 5th Generation New Radio (5G NR) system, a Long Term Evolution (LTE) system, and a Wireless Local Area Network (WLAN) system.

A frequency division duplex (FDD) band to which a plurality of power classes including a first power class and a second power class are applicable can be used as Band A. More specifically, Band 1, Band 3, Band 5, Band 7, Band 8, Band 26, Band 28, or Band 71 for LTE or n1, n3, n5, n7, n8, n28, or n71 for 5G NR can be used as Band A. Note that Band A is not limited to the above and for example, a time division duplex (TDD) band or a supplementary uplink (SUL) band may be used. For example, Band 40 or Band 41 for LTE or n40 or n41 for 5G NR may be used as Band A.

The power classes are classifications of output powers of UEs defined based on maximum output powers, and the smaller the value of the power class is, the higher output power is allowed. For example, according to the 3GPP, the maximum output power of power class 1 is defined to be 31 dBm, the maximum output power of power class 1.5 is defined to be 29 dBm, the maximum output power of power class 2 is defined to be 26 dBm, the maximum output power of power class 3 is defined to be 23 dBm, and the maximum output power of power class 5 is defined to be 20 dBm.

The maximum output power is defined based on the maximum output power of an antenna terminal. The maximum output power of a UE is measured by using a method defined by the 3GPP, for instance. For example, in FIG. 1, the maximum output power is measured by measuring radiant power at antenna 2. Note that instead of measuring radiant power, a terminal is provided in the vicinity of antenna 2 and a measuring instrument (a spectrum analyzer, for example) is connected to the terminal, whereby the maximum output power of antenna 2 can be measured.

Here, the first power class allows a maximum output power higher than the maximum output power of the second power class. For example, Power Class 2 can be used as the first power class, and Powe Class 3 can be used as the second power class. Note that the first power class and the second power class are not limited to Power Classes 2 and 3, respectively.

Combiner 41 is an example of a first combiner, and includes terminals 411 to 413. Terminal 411 is an example of a first input terminal, and is connected to filter 31 via switch 51. Terminal 412 is an example of a second input terminal, and is connected to filter 32 via switch 51. Terminal 413 is an example of an output terminal, and is connected to antenna connection terminal 100 via switch 52. Accordingly, combiner 41 can combine a transmission signal in Band

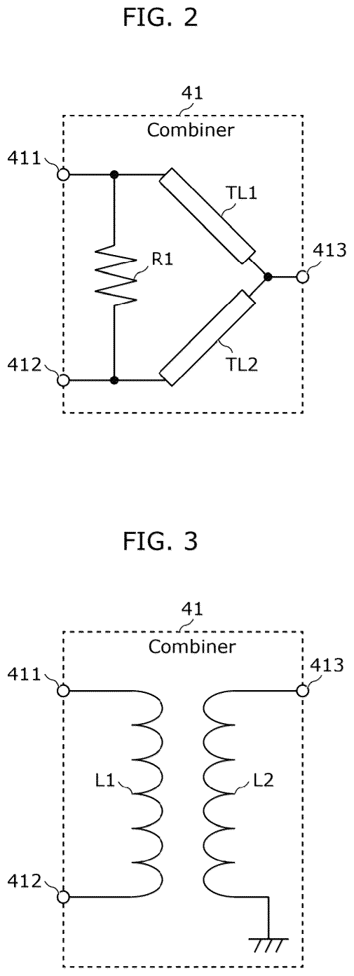

A that has passed through filter 31 and a transmission signal in Band A that has passed through filter 32, and output the resultant signal to antenna connection terminal 100. Various combiners can be used as combined 41 according to a phase difference between two input signals. Specific examples of combiner 41 are to be described later with reference to FIG. 2 to FIG. 4.

Switch 51 is an example of a first switch, and includes terminals 511 to 515. Terminal 511 is an example of a first terminal, and is connected to the one end of filter 31. Terminal 512 is an example of a second terminal, and is connected to the one end of filter 32. Terminal 513 is an example of a third terminal, and is connected to terminal 411 of combiner 41. Terminal 514 is an example of a fourth terminal, and is connected to terminal 412 of combiner 41. Terminal 515 is an example of a fifth terminal, and is connected to terminal 523 of switch 52.

With this connection configuration, switch 51 can connect terminal 511 exclusively to terminal 513 or can connect terminal 511 exclusively to terminal 515 and can connect terminal 512 to terminal 514 based on a control signal from RFIC 3, for example. Switch 51 includes a combination of a single-pole double-throw (SPDT) switch circuit and a single-pole single-throw (SPST) switch circuit, for example.

Switch 52 is an example of a second switch, and includes terminals 521 to 523. Terminal 521 is an example of a first terminal, and is connected to antenna connection terminal 100. Terminal 522 is an example of a second terminal, and is connected to terminal 413 of combiner 41. Terminal 523 is an example of a third terminal, and is connected to terminal 515 of switch 51.

With this connection configuration, switch 52 can connect terminal 521 exclusively to terminal 522 or can connect terminal 521 exclusively to terminal 523, based on a control signal from RFIC 3, for example. Switch 52 includes an SPDT switch circuit, for example.

Note that switch circuit 52 may not be included in radio frequency circuit 1. In this case, terminal 515 of switch 51 and terminal 413 of combiner 41 may be directly connected to antenna connection terminal 100.

### [1.3 Circuit Configuration of Combiner 41]

Next, circuit configurations of combiner 41 according to the present embodiment are to be described with reference to FIG. 2 to FIG. 4. FIG. 2 to FIG. 4 illustrate circuit configurations of different examples of combiner 41 according to the present embodiment.

Note that FIG. 2 to FIG. 4 illustrate exemplary circuit configurations, and combiner 41 may be implemented using any of various types of circuit implementations and circuit technologies. Thus, the description of combiner 41 provided below should not be interpreted in a limited manner.

In the example in FIG. 2, combiner 41 is a Wilkinson coupler, and includes transfer lines TL1 and TL2 and resistor R1. Transfer line TL1 is connected between terminal 411 and terminal 413 and is a quarter-wavelength transfer line for Band A. Transfer line TL2 is connected between terminal 412 and terminal 413 and is a quarter-wavelength transfer line for Band A. Note that transfer lines TL1 and TL2 may each include an inductor and/or a capacitor. Resistor R1 is connected between terminals 411 and 412, in parallel to transfer lines TL1 and TL2. With this configuration, combiner 41 can combine two in-phase transmission signals in Band A that have passed through filters 31 and 32 into one signal.

In the example in FIG. 3, combiner 41 is a transformer, and includes primary coil L1 and secondary coil L2 coupled to primary coil L1. Two ends of primary coil L1 are connected to terminals 411 and 412. One end of secondary coil L2 is connected to terminal 413, and another end of secondary coil L2 is connected to the ground. With this configuration, combiner 41 can combine two antiphase transmission signals (that is, differential signals) in Band A that have passed through filters 31 and 32 into one signal.

As illustrated in FIG. 3, in a case in which a transformer is used as combiner 41, power amplifiers 11 and 12 and combiner 41 are included in a differential-amplifier type amplifier circuit. At this time, power amplifier 11 amplifies one of the differential signals, and power amplifier 12 amplifies the other of the differential signals. Then, combiner 41 combines the differential signals amplified by power amplifiers 11 and 12.

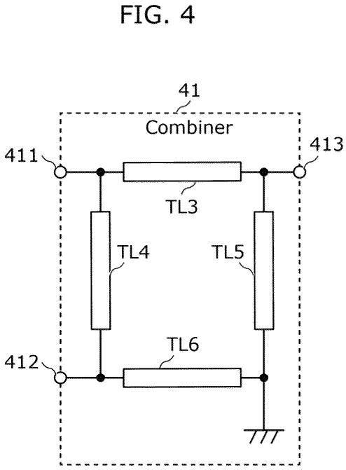

In the example in FIG. 4, combiner 41 is a 90-degree hybrid coupler, and includes transfer lines TL3 to TL6. Transfer line TL3 is connected between terminal 411 and terminal 413. Transfer line TL4 is connected between terminal 411 and terminal 412. Transfer lines TL5 and TL6 are connected in series between terminal 412 and terminal 413. With this configuration, combiner 41 can combine two transmission signals in Band A having a phase difference of 90 degrees, which have passed through filters 31 and 32, into one signal.

Note that quarter-wavelength transfer lines may be used as transfer lines TL3 to TL6, but transfer lines TL3 to TL6 are not limited thereto. For example, LC circuits may be used as transfer lines TL3 to TL6.

### [1.4 Modes of Radio Frequency Circuit 1]

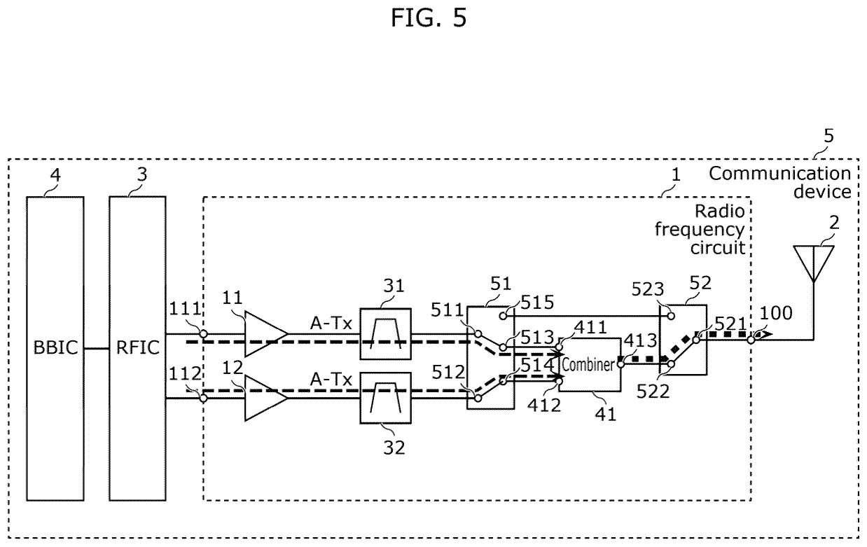

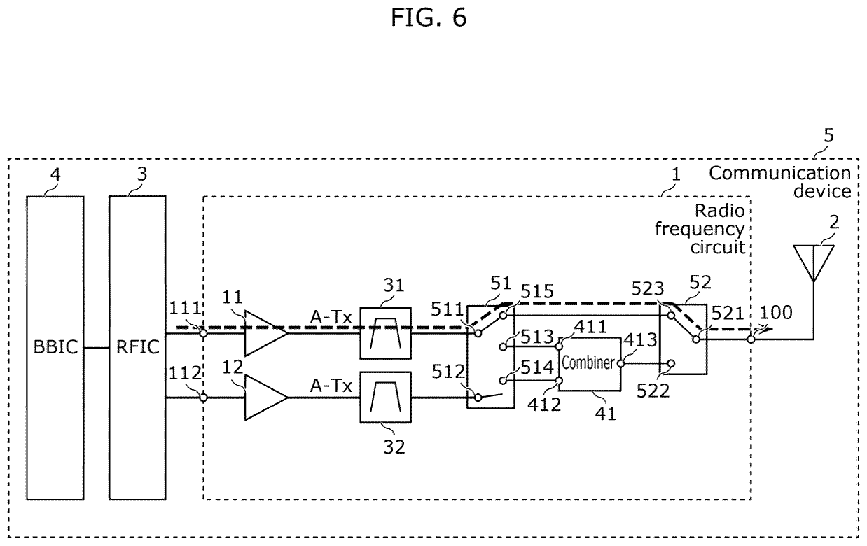

Next, a plurality of modes of radio frequency circuit 1 are to be described with reference to FIG. 5 and FIG. 6. In FIG. 5 and FIG. 6, broken-line arrows represent transmission paths.

First, a first mode of radio frequency circuit 1 is to be described with reference to FIG. 5. FIG. 5 illustrates transmission paths in the first mode of radio frequency circuit 1 according to the present embodiment.

The first mode is a control mode used under a condition that the first power class is applied to Band A and a signal in Band A is transmitted. In the first mode, two transmission filters (filters 31 and 32) for Band A are connected to antenna connection terminal 100 via combiner 41, as illustrated in FIG. 5. Specifically, terminal 511 is connected to terminal 513 and not connected to terminal 515 in switch 51. Furthermore, terminal 512 is connected to terminal 514. Terminal 521 is connected to terminal 522 and not connected to terminal 523 in switch 52.

Accordingly, a transmission signal in Band A received from RFIC 3 via radio frequency input terminal 111 is transferred to terminal 411 of combiner 41 via power amplifier 11, filter 31, and switch 51. Furthermore, a transmission signal in Band A received from RFIC 3 via radio frequency input terminal 112 is transferred to terminal 412 of combiner 41 via power amplifier 12, filter 32, and switch 51. The two transmission signals in Band A input to terminals 411 and 412 of combiner 41 are combined into one signal, and the resultant signal is transferred to antenna connection terminal 100 via switch 52. Next, a second mode of radio frequency circuit 1 is to be described with reference to FIG. 6. FIG. 6 illustrates a transmission path in the second mode of radio frequency circuit 1 according to the present embodiment.

The second mode is a control mode used under a condition that the second power class is applied to Band A and a signal in Band A is transmitted. In the second mode, only one (filter 31) of the two transmission filters for Band A is connected to antenna connection terminal 100 not via combiner 41, as illustrated in FIG. 6. Specifically, terminal 511 is connected to terminal 515 and not connected to terminal 513 in switch 51. Furthermore, terminal 512 is not connected to terminal 514. Terminal 521 is connected to terminal 523 and not connected to terminal 522 in switch 52.

Accordingly, a transmission signal in Band A received from RFIC 3 via radio frequency input terminal 111 is transferred to antenna connection terminal 100 via power amplifier 11, filter 31, and switches 51 and 52.

Note that here, the mode applied to radio frequency circuit 1 is selected based on a power class, but the present embodiment is not limited thereto. For example, the mode applied to radio frequency circuit 1 may be selected from among the first mode and the second mode, based on required signal quality and/or power efficiency for transmission. Specifically, the first mode may be used in a case in which signal quality is prioritized in transmitting a signal in Band A, whereas the second mode may be used in a case in which power efficiency is prioritized in transmitting a signal in Band A. The mode applied to radio frequency circuit 1 may be selected based a combination of a power class and signal quality and/or power efficiency. Specifically, the first mode is used under a condition that the first power class is applied to Band A, whereas the second mode is used in a case in which power efficiency is prioritized under a condition that the second power class is applied to Band A. Here, the first mode may be used in a case in which signal quality is prioritized even under a condition that the second power class is applied to Band A.

### [1.5 Advantageous Effects and Others]

As described above, radio frequency circuit 1 according to the present embodiment includes: filter 31 having a passband that includes a transmission band of Band A to which a plurality of power classes are applicable; filter 32 having a passband that includes the transmission band of Band A; combiner 41 that includes terminals 411 to 413; and switch 51 that includes terminals 511 to 515. Terminal 413 of combiner 41 is connected to antenna connection terminal 100. Terminal 511 of switch 51 is connected to one end of filter 31. Terminal 512 of switch 51 is connected to one end of filter 32. Terminal 513 of switch 51 is connected to terminal 411 of combiner 41. Terminal 514 of switch 51 is connected to terminal 412 of combiner 41, and terminal 515 of switch 51 is connected to antenna connection terminal 100 not via combiner 41.

According to this, two filters 31 and 32 that include a transmission band of Band A to which a plurality of power classes are applicable can be connected to antenna connection terminal 100 via combiner 41. Thus, combiner 41 can combine two transmission signals in Band A and output the resultant signal to antenna connection terminal 100. As a result, for example, under a condition that a higher power class (power class 2, for example) is applied, maximum powers of transmission signals in Band A that pass through filters 31 and 32 can be decreased. Stated differently, required power durability for two filters 31 and 32 can be decreased, and higher power classes can be more readily supported. Furthermore, filters 31 and 32 can be connected to antenna connection terminal 100 not via combiner 41. Thus, signal loss due to combiner 41 can be avoided, and thus power efficiency can be improved, for example, under a condition that a lower power class (Power Class 3, for example) is applied.

For example, in radio frequency circuit 1 according to the present embodiment, Band A may be a frequency division duplex (FDD) band.

According to this, an FDD band is used for Band A to which a plurality of power classes are applicable. In an FDD band, signals are continuously transmitted, and thus required power durability for a filter is higher than that in a case of a time division duplex (TDD) band. Thus, under a condition that an FDD band is used for Band A, the effect of lowering required power durability for two filters 31 and 32 is significant.

For example, radio frequency circuit 1 according to the present embodiment may further include: power amplifier 11 connected to another end of filter 31; and power amplifier 12 connected to another end of filter 32.

According to this, two transmission signals in Band A that are amplified by two power amplifiers 11 and 12 can be combined by combiner 41, and the resultant signal can be output to antenna connection terminal 100. Thus, required output power for power amplifiers 11 and 12 in a higher power class, for example, can be lowered. Stated differently, amplification performance that two power amplifiers 11 and 12 are to exhibit can be lowered, and higher power classes can be more readily supported.

For example, in radio frequency circuit 1 according to the present embodiment, power amplifiers 11 and 12 and combiner 41 may be included in a differential-amplifier type power amplifier, combiner 41 may be a transformer that includes primary coil L1 and secondary coil L2, and in combiner 41, terminal 411 may be connected to one end of primary coil L1, terminal 412 may be connected to another end of primary coil L1, and terminal 413 may be connected to one end of secondary coil L2.

According to this, two antiphase transmission signals in Band A (that is, differential signals) can be amplified by using a differential-amplifier type amplifier circuit, and spurious emission (in particular, even-ordered harmonic distortion) can be attenuated.

For example, radio frequency circuit 1 according to the present embodiment may further include switch 52 that includes terminals 521 to 523, terminal 521 of switch 52 may be connected to antenna connection terminal 100, terminal 522 of switch 52 may be connected to terminal 413 of combiner 41, and terminal 523 of switch 52 may be connected to terminal 515 of switch 51.

According to this, switch 52 can switch between a path that connects two filters 31 and 32 to antenna connection terminal 100 via combiner 41 and a path that connects filter 31 or 32 to antenna connection terminal 100 not via combiner 41. Thus, isolation between the two paths can be enhanced.

For example, radio frequency circuit 1 according to the present embodiment may have a first mode and a second mode, in the first mode, (i) in switch 51, terminal 511 may be connected to terminal 513 and terminal 512 may be connected to terminal 514 and (ii) in switch 52, terminal 521 may be connected to terminal 522, and in the second mode, (i) in switch 51, terminal 511 may be connected to terminal 515 and (ii) in switch 52, terminal 521 may be connected to terminal 523.

According to this, two filters 31 and 32 are connected to antenna connection terminal 100 via combiner 41 by using the first mode, and filter 31 is connected to antenna connection terminal 100 not via combiner 41 by using the second mode.

For example, in radio frequency circuit 1 according to the present embodiment, the plurality of power classes may include a first power class and a second power class, in the first power class, a maximum output power higher than a maximum output power of the second power class may be allowed, the first mode may be used under a condition that the first power class is applied to Band A, and the second mode may be used under a condition that the second power class is applied to Band A.

According to this, by using the first mode in a higher power class (that is, the first power class), maximum powers of transmission signals in Band A that pass through filters 31 and 32 can be lowered, and required power durability for two filters 31 and 32 can be decreased. Furthermore, in a lower power class (that is, the second power class), signal loss due to combiner 41 can be avoided, and thus power efficiency can be improved.

For example, in radio frequency circuit 1 according to the present embodiment, the plurality of power classes may include a first power class and a second power class, in the first power class, a maximum output power higher than a maximum output power of the second power class may be allowed, the first mode may be used under a condition that the first power class is applied to Band A or signal quality is prioritized over power efficiency in transmitting a signal in Band A, and the second mode may be used under a condition that the second power class is applied to Band A and power efficiency is prioritized over signal quality in transmitting a signal in Band A.

According to this, by using the first mode in a higher power class (that is, the first power class), maximum powers of transmission signals in Band A that pass through filters 31 and 32 can be lowered, and required power durability for two filters 31 and 32 can be decreased. Furthermore, by using the second mode in a lower power class (that is, the second power class) under a condition that power efficiency is prioritized, signal loss due to combiner 41 can be avoided, and thus power efficiency can be improved. On the other hand, even in a lower power class (that is, the second power class), under a condition that signal quality is prioritized, two transmission signals in Band A can be combined by using the first mode, and spurious emission can be reduced in particular in a case in which a differential-amplifier type amplifier circuit is used.

### Variation of Embodiment 1

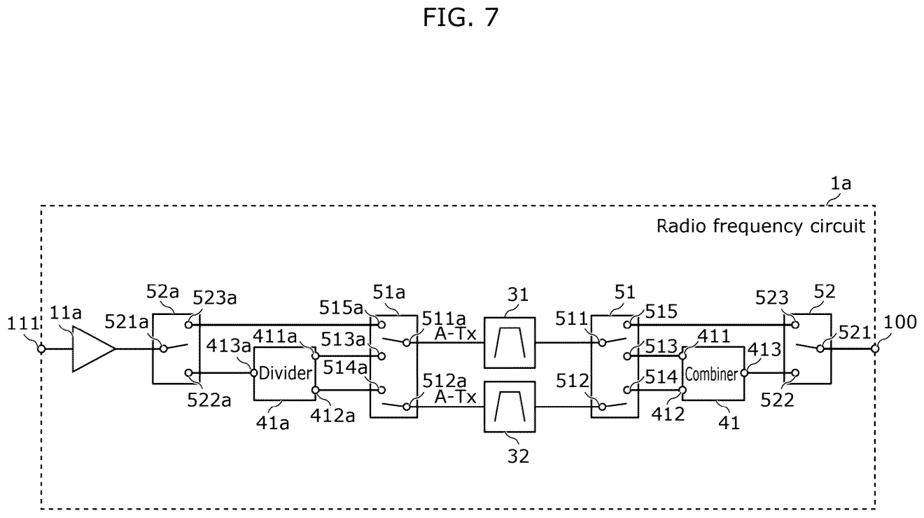

Next, a variation of Embodiment 1 is to be described. This variation is mainly different from Embodiment 1 above in that only one power amplifier is included in a radio frequency circuit. In the following, this variation is to be described with reference to FIG. 7, focusing on different points from Embodiment 1 above.

FIG. 7 illustrates a circuit configuration of radio frequency circuit 1a according to a variation of Embodiment 1. Note that FIG. 7 illustrates an exemplary circuit configuration, and radio frequency circuit 1a may be implemented using any of various types of circuit implementations and circuit technologies. Thus, the description of radio frequency circuit 1a provided below should not be interpreted in a limited manner.

Radio frequency circuit 1a includes power amplifier 11a, filters 31 and 32, combiner 41, divider 41a, switches 51, 51a, 52, and 52a, antenna connection terminal 100, and radio frequency input terminal 111.

The input end of power amplifier 11a is connected to radio frequency input terminal 111. The output end of power amplifier 11a is connected to switch 52a. Power amplifier 11a can amplify input signals (transmission signals in Band A in this variation) from radio frequency input terminal 111, by using power supplied from a power source (not illustrated), similarly to power amplifier 11. Note that in this variation, power amplifier 11a can amplify a transmission signal in Band A to have power corresponding to the maximum output power of the first power class.

Divider 41a includes terminals 411a to 413a. Terminal 411a is connected to filter 31 via switch 51a. Terminal 412a is connected to filter 32 via switch 51a. Terminal 413a is connected to the output end of power amplifier 11a via switch 52a. Accordingly, divider 41a can divide a transmission signal in Band A amplified by power amplifier 11a into two signals and output the signals to filters 31 and 32. A similar configuration to that of combiner 41 can be used for divider 41a, and for example, combiner 41 in FIG. 2 to FIG. 4 may be used as divider 41a.

Switch 51a includes terminals 511a to 515a. Terminal 511a is connected to the other end of filter 31. Terminal 512a is connected to the other end of filter 32. Terminal 513a is connected to terminal 411a of divider 41a. Terminal 514a is connected to terminal 412a of divider 41a. Terminal 515a is connected to terminal 523a of switch 52a.

With this connection configuration, switch 51a can connect terminal 511a exclusively to terminal 513a or can connect terminal 511a exclusively to terminal 515a and can connect terminal 512a to terminal 514a based on a control signal from RFIC 3, for example. Switch 51a includes a combination of an SPDT switch circuit and an SPST switch circuit, for example.

Switch 52a includes terminals 521a to 523a. Terminal 521a is connected to the output end of power amplifier 11a. Terminal 522a is connected to terminal 413a of divider 41a. Terminal 523a is connected to terminal 515a of switch 51a.

With this connection configuration, switch 52a can connect terminal 521a exclusively to terminal 522a or can connect terminal 521a exclusively to terminal 523a, based on a control signal from RFIC 3, for example. Switch 52a includes an SPDT switch circuit, for example.

Switches 51a and 52a operate similarly to switches 51 and 52. Specifically, in the first mode, terminal 511a is connected to terminal 513a and not connected to terminal 515a in switch 51a. Furthermore, terminal 512a is connected to terminal 514a. Terminal 521a is connected to terminal 522a and not connected to terminal 523a in switch 52a. On the other hand, in the second mode, terminal 511a is connected to terminal 515a and not connected to terminal 513a in switch 51a. Furthermore, terminal 512a is not connected to terminal 514a. Terminal 521a is connected to terminal 523a and not connected to terminal 522a in switch 52a.

As described above, radio frequency circuit 1a according to this variation includes: power amplifier 11a; divider 41a that includes terminals 411a to 413a; and switch 51a that includes terminals 511a to 515a. Terminal 413a of divider 41a is connected to an output end of power amplifier 11a, terminal 511a of switch 51a is connected to another end of filter 31, terminal 512a of switch 51a is connected to another end of filter 32, terminal 513a of switch 51a is connected to terminal 411a of divider 41a, terminal 514a of switch 51a is connected to terminal 412a of divider 41a, and terminal 515a of switch 51a is connected to an output end of power amplifier 11a not via divider 41a.

According to this, a transmission signal amplified by power amplifier 11a can be divided by using divider 41a, and thus the number of power amplifiers can be reduced as compared with radio frequency circuit 1 according to Embodiment 1 above.

### Embodiment 2

Next, Embodiment 2 is to be described. In the present embodiment, a main difference from Embodiment 1 above is that Band B is also supported to which a plurality of power classes that include the first power class and the second power class are applicable in addition to Band A. In the following, the present embodiment is to be described with reference to the drawings, focusing on different points from Embodiment 1 above.

Note that a circuit configuration of communication device 5A according to the present embodiment is similar to the circuit configuration of communication device 5 according to Embodiment 1 above except that radio frequency circuit 1A is included instead of radio frequency circuit 1, and thus a description thereof is omitted.

### [2.1 Circuit Configuration of Radio Frequency Circuit 1A]

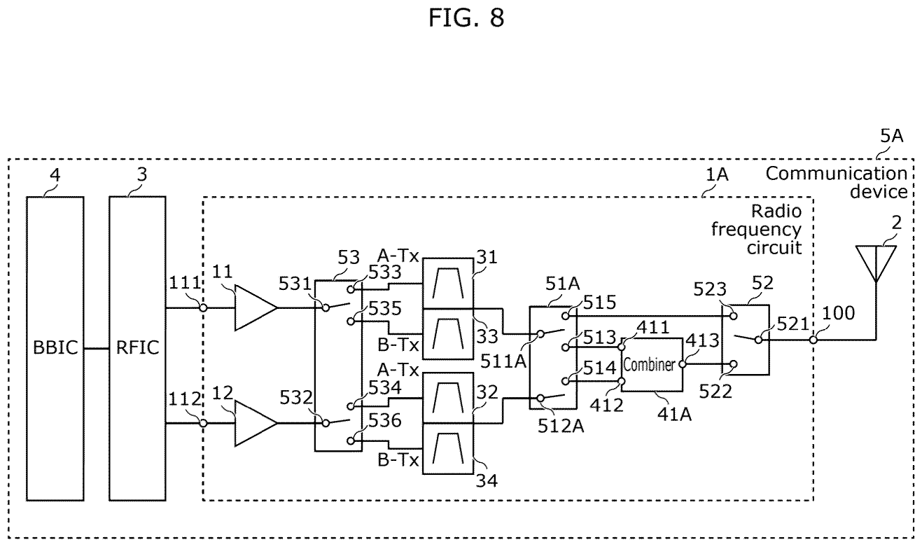

A circuit configuration of radio frequency circuit 1A is to be described with reference to FIG. 8. FIG. 8 illustrates a circuit configuration of communication device 5A according to the present embodiment.

Note that FIG. 8 illustrates an exemplary circuit configuration, and communication device 5A and radio frequency circuit 1A may be implemented using any of various types of circuit implementations and circuit technologies. Thus, the description of radio frequency circuit 1A provided below should not be interpreted in a limited manner.

Radio frequency circuit 1A includes power amplifiers 11 and 12, filters 31 to 34, combiner 41A, switches 51A, 52, and 53, antenna connection terminal 100, and radio frequency input terminals 111 and 112.

Filter 33 is an example of a third filter, and is connected between antenna connection terminal 100 and radio frequency input terminal 111. Specifically, one end of filter 33 is connected to switch 51A, and another end of filter 33 is connected to switch 53. Filter 33 is a bandpass filter having a passband that includes a transmission band of Band B. Note that filter 33 is not limited to a bandpass filter.

Filter 34 is an example of a fourth filter, and is connected between antenna connection terminal 100 and radio frequency input terminal 112. Specifically, one end of filter 34 is connected to switch 51A, and another end of filter 34 is connected to switch 53. Filter 34 is a bandpass filter having a passband that includes a transmission band of Band B. Note that filter 34 is not limited to a bandpass filter.

A SAW filter, a BAW filter, an LC resonator filter, a dielectric resonator filter, or a combination of any of these may be used as such filters 33 and 34 similarly to filters 31 and 32, and furthermore, filters 33 and 34 are not limited to these.

Similarly to Band A, Band B is a frequency band for a communication system constructed by using RAT and is defined in advance by a standardizing body, for instance. As Band B, a FDD band which is different from Band A and to which a plurality of power classes including the first power class and the second power class are applicable can be used. More specifically, Band 1, Band 3, Band 5, Band 7, Band 8, Band 26, Band 28, or Band 71 for LTE or n1, n3, n5, n7, n8, n28, or n71 for 5G NR can be used as Band B. Note that Band B is not limited to the above bands and a TDD band or an SUL band may be used, for example. For example, Band 40 or Band 41 for LTE or n40 or n41 for 5G NR may be used as Band B.

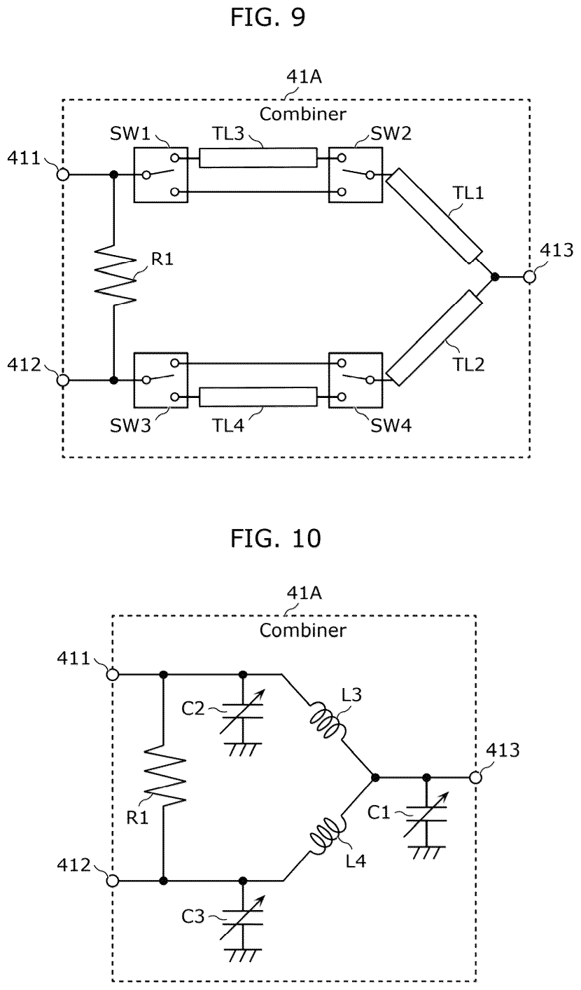

Combiner 41A is an example of a first combiner, and includes terminals 411 to 413, similarly to combiner 41. Combiner 41A can combine two transmission signals in Band A that have passed through filters 31 and 32 and output the resultant signal to antenna connection terminal 100. Furthermore, combiner 41A can combine two transmission signals in Band B that have passed through filters 33 and 34 and output the resultant signal to antenna connection terminal 100. A specific example of combiner 41A is to be described later with reference to FIG. 9 to FIG. 11.

Switch 51A is an example of a first switch, and includes terminals 511A, 512A, and 513 to 515. Terminal 511A is an example of a first terminal, and is connected to one end of filter 31 and one end of filter 33. Terminal 512A is an example of a second terminal, and is connected to one end of filter 32 and one end of filter 34.

With this connection configuration, switch 51 can connect terminal 511A exclusively to terminal 513 or can connect terminal 511A exclusively to terminal 515 and can connect terminal 512A to terminal 514, based on a control signal from RFIC 3, for example. Switch 51A includes a combination of an SPDT switch circuit and an SPST switch circuit, for example.

Switch 53 is an example of a third switch, and includes terminals 531 to 536. Terminal 531 is an example of a first terminal, and is connected to the output end of power amplifier 11. Terminal 532 is an example of a second terminal, and is connected to the output end of power amplifier 12. Terminal 533 is an example of a third terminal, and is connected to the other end of filter 31. Terminal 534 is an example of a fourth terminal, and is connected to the other end of filter 32. Terminal 535 is an example of a fifth terminal, and is connected to the other end of filter 33. Terminal 536 is an example of a sixth terminal, and is connected to the other end of filter 34.

With this connection configuration, switch 53 can connect terminal 531 exclusively to terminal 533 or can connect terminal 531 exclusively to terminal 535. Switch 53 can also connect terminal 532 exclusively to one of terminals 534 to 536, based on a control signal from RFIC 3, for example. That is, the control signal from RFIC 3 can cause switch 53 to connect terminal 532 exclusively to terminal 534, or to connect terminal 532 exclusively to terminal 535, or to connect terminal 532 exclusively to terminal 536. Switch 53 includes a combination of two SPDT switch circuits and a single-pole triple-throw (SP3T) switch circuit, for example.

### [2.2 Circuit Configuration of Combiner 41A]

Next, a circuit configuration of combiner 41A according to the present embodiment is to be described with reference to FIG. 9 to FIG. 11. FIG. 9 to FIG. 11 illustrate circuit configurations of different examples of combiner 41A according to the present embodiment.

Note that FIG. 9 to FIG. 11 illustrate exemplary circuit configurations, and combiner 41A may be implemented using any of various types of circuit implementations and circuit technologies. Thus, the description of combiner 41A provided below should not be interpreted in a limited manner.

In the example in FIG. 9, combiner 41A is a Wilkinson coupler that supports Bands A and B, and includes transfer lines TL1 to TL4, resistor R1, and switches SW1 to SW4.

Transfer line TL3 is connected between transfer line TL1 and terminal 411. Transfer lines TL1 and TL3 are quarter-wavelength transfer lines for Band B. Transfer line TL4 is connected between transfer line TL2 and terminal 412. Transfer lines TL2 and TL4 are quarter-wavelength transfer lines for Band B.

Switch SW1 includes a terminal connected to terminal 411, a terminal connected to switch SW2 via transfer line TL3, and a terminal connected to switch SW2 not via transfer line TL3. Switch SW2 includes a terminal connected to transfer line TL1, a terminal connected to switch SW1 via transfer line TL3, and a terminal connected to switch SW1 not via transfer line TL3. With this configuration, switches SW1 and SW2 can switch between connection and disconnection of transfer line TL3 between transfer line TL1 and terminal 411. Thus, switches SW1 and SW2 can switch between (i) connection of transfer line TL1 and disconnection of transfer line TL3 and (ii) series connection of transfer lines TL1 and TL3, between terminal 411 and terminal 413.

Switch SW3 includes a terminal connected to terminal 412, a terminal connected to switch SW4 via transfer line TL4, and a terminal connected to switch SW4 not via transfer line TL4. Switch SW4 includes a terminal connected to transfer line TL2, a terminal connected to switch SW3 via transfer line TL4, and a terminal connected to switch SW3 not via transfer line TL4. With this configuration, switches SW3 and SW4 can switch between connection and disconnection of transfer line TL4 between transfer line TL2 and terminal 412. Thus, switches SW3 and SW4 can switch between (i) connection of transfer line TL2 and disconnection of transfer line TL4 and (ii) series connection of transfer lines TL2 and TL4, between terminal 412 and terminal 413.

Such combiner 41A can combine two in-phase transmission signals in Band A by (i) connecting transfer line TL1 and disconnecting transfer line TL3, between terminal 411 and terminal 413 and (ii) connecting transfer line TL2 and disconnecting transfer line TL4, between terminal 412 and terminal 413. On the other hand, combiner 41A can combine two in-phase transmission signals in Band B by (i) connecting transfer lines TL1 and TL3 in series between terminals 411 and 413 and (ii) connecting transfer lines TL2 and TL4 in series between terminals 412 and 413.

In the example in FIG. 10, combiner 41A is a Wilkinson coupler that supports Bands A and B, and includes inductors L3 and L4, variable capacitors C1 to C3, and resistor R1. The example in FIG. 10 is different from the example in FIG. 9 in that inductors and variable capacitors are used instead of transfer lines and switches.

Inductor L3 is connected between terminals 411 and 413. Inductor L4 is connected between terminals 412 and 413. Variable capacitor C1 is connected between the ground and a path between terminal 413 and inductors L3 and L4. Variable capacitor C2 is connected between the ground and a path between terminal 411 and inductor L3. Variable capacitor C3 is connected between the ground and a path between terminal 412 and inductor L4.

Such combiner 41A can combine two in-phase transmission signals in Band A and combine two in-phase transmission signals in Band B, by changing capacitance of variable capacitors C1 to C3 according to whether signals are in Band A or Band B.

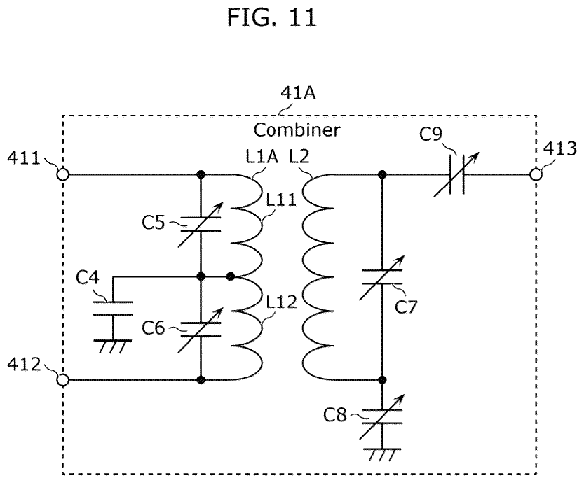

In the example in FIG. 11, combiner 41A is a transformer, and includes primary coil L1A, secondary coil L2 coupled to primary coil L1A, capacitor C4, and variable capacitors C5 to C9.

Primary coil L1A includes subcoils L11 and L12. One end of subcoil L11 is connected to terminal 411 and one end of variable capacitor C5. One end of subcoil L12 is connected to terminal 412 and one end of variable capacitor C6. Another end of subcoil L11 is connected to another end of subcoil L12 at an intermediate point of primary coil L1A.

One end of secondary coil L2 is connected to terminal 413 via variable capacitor C9 and connected to one end of variable capacitor C7. Another end of secondary coil L2 is connected to another end of variable capacitor C7 and connected to the ground via variable capacitor C8.

One end of capacitor C4 is connected to the intermediate point of primary coil L1A (that is, the other end of subcoil L11 and the other end of subcoil L12), another end of variable capacitor C5, and another end of variable capacitor C6. Another end of capacitor C4 is connected to the ground.

One end of variable capacitor C5 is connected to one end of primary coil L1A (that is, the one end of subcoil L11) and terminal 411. The other end of capacitor C5 is connected to the intermediate point of primary coil L1A (that is, the other end of subcoil L11 and the other end of subcoil L12), the other end of variable capacitor C6, and the one end of capacitor C4.

The one end of variable capacitor C6 is connected to another end of primary coil L1A (that is, the one end of subcoil L12) and terminal 412. The other end of capacitor C6 is connected to the intermediate point of primary coil L1A (that is, the other end of subcoil L11 and the other end of subcoil L12), the other end of variable capacitor C5, and the one end of capacitor C4.

The one end of variable capacitor C7 is connected to the one end of secondary coil L2 and is connected to terminal 413 via variable capacitor C9. The other end of variable capacitor C7 is connected to the other end of secondary coil L2 and is connected to the ground via variable capacitor C8.

One end of variable capacitor C8 is connected to the other end of secondary coil L2 and the other end of variable capacitor C7. Another end of capacitor C8 is connected to the ground.

One end of variable capacitor C9 is connected to the one end of secondary coil L2 and the one end of variable capacitor C7. Another end of variable capacitor C9 is connected to terminal 413.

Such combiner 41A can combine signals in a plurality of bands by changing capacitance of variable capacitors C5 to C9 according to whether signals are in Band A or B. Specifically, combiner 41A can combine two antiphase transmission signals in Band A and combine two antiphase transmission signals in Band B.

### [2.3 Modes of Radio Frequency Circuit 1A]

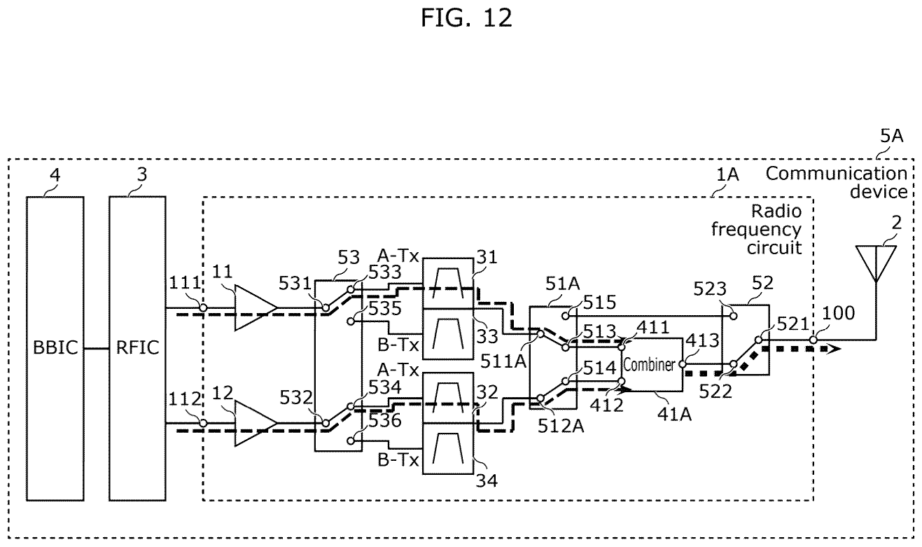

Next, a plurality of modes of radio frequency circuit 1A are to be described with reference to FIG. 12 to FIG. 14. In FIG. 12 to FIG. 14, broken-line arrows represent transmission paths.

First, a first mode of radio frequency circuit 1A is to be described with reference to FIG. 12. FIG. 12 illustrates transmission paths in the first mode of radio frequency circuit 1A according to the present embodiment.

The first mode is a control mode used under a condition that the first power class is applied to Band A and a signal in Band A is transmitted. In the first mode, two transmission filters (filters 31 and 32) for Band A are connected to antenna connection terminal 100 via combiner 41A, as illustrated in FIG. 12. Specifically, terminal 511A is connected to terminal 513 and not connected to terminal 515 in switch 51A. Furthermore, terminal 512A is connected to terminal 514. Terminal 521 is connected to terminal 522 and not connected to terminal 523 in switch 52. Terminal 531 is connected to terminal 533 and not connected to terminal 535 in switch 53. Furthermore, terminal 532 is connected to terminal 534 and not connected to terminal 535 or 536.

Accordingly, a transmission signal in Band A received from RFIC 3 via radio frequency input terminal 111 is transferred to terminal 411 of combiner 41A via power amplifier 11, switch 53, filter 31, and switch 51A. Furthermore, a transmission signal in Band A received from RFIC 3 via radio frequency input terminal 112 is transferred to terminal 412 of combiner 41A via power amplifier 12, switch 53, filter 32, and switch 51A. Two transmission signals in Band A input to terminals 411 and 412 of combiner 41A are combined into one signal, and the resultant signal is transferred to antenna connection terminal 100 via switch 52.

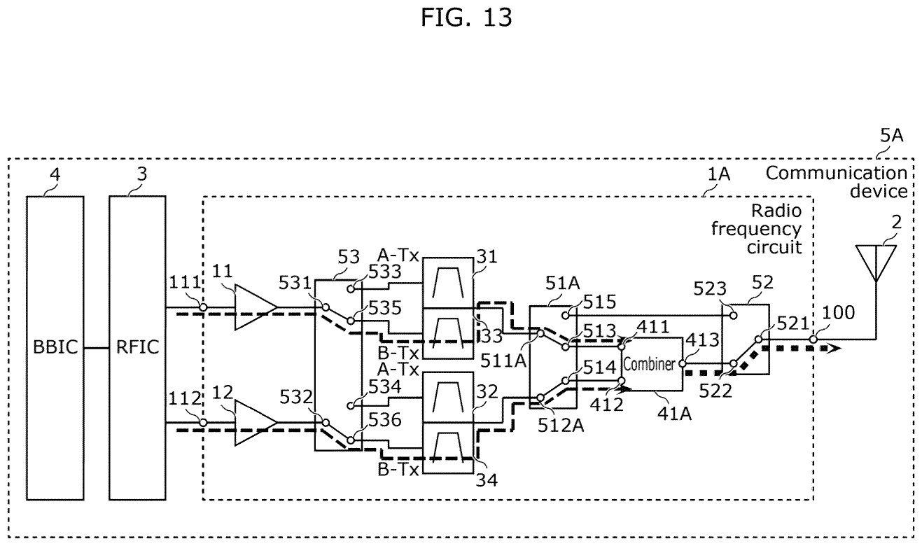

Next, a second mode of radio frequency circuit 1A is to be described with reference to FIG. 13. FIG. 13 illustrates transmission paths in the second mode of radio frequency circuit 1A according to the present embodiment.

The second mode is a control mode used under a condition that the first power class is applied to Band B and signals in Band B are transmitted. In the second mode, two transmission filters (filters 33 and 34) for Band B are connected to antenna connection terminal 100 via combiner 41A, as illustrated in FIG. 13. Specifically, terminal 511A is connected to terminal 513 and not connected to terminal 515 in switch 51A. Furthermore, terminal 512A is connected to terminal 514. Terminal 521 is connected to terminal 522 and not connected to terminal 523 in switch 52. Terminal 531 is connected to terminal 535 and not connected to terminal 533 in switch 53. Furthermore, terminal 532 is connected to terminal 536 and not connected to terminal 534 or 535.

Accordingly, a transmission signal in Band B received from RFIC 3 via radio frequency input terminal 111 is transferred to terminal 411 of combiner 41A via power amplifier 11, switch 53, filter 33, and switch 51A. Furthermore, a transmission signal in Band B received from RFIC 3 via radio frequency input terminal 112 is transferred to terminal 412 of combiner 41A via power amplifier 12, switch 53, filter 34, and switch 51A. The two transmission signals in Band B input to terminals 411 and 412 of combiner 41A are combined into one signal, and the resultant signal is transferred to antenna connection terminal 100 via switch 52.

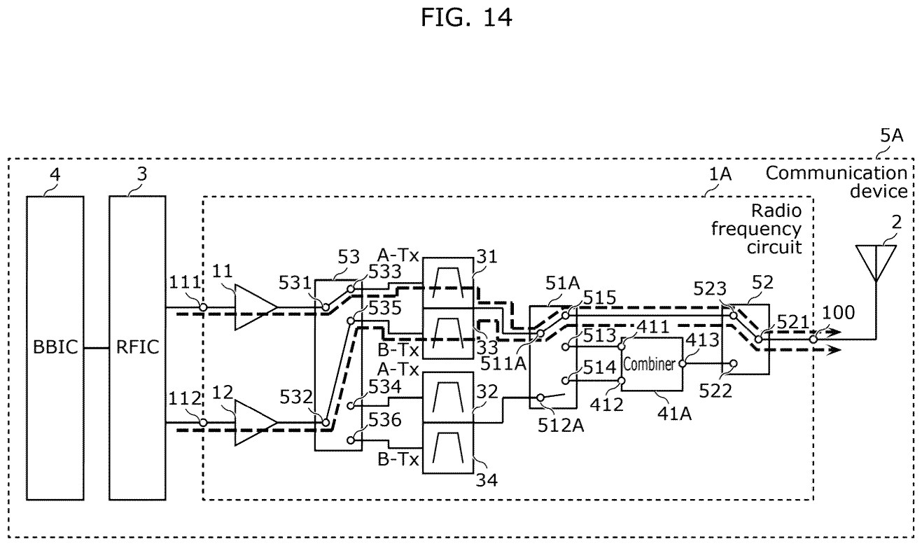

Next, a third mode of radio frequency circuit 1A is to be described with reference to FIG. 14. FIG. 14 illustrates transmission paths in the third mode of radio frequency circuit 1A according to the present embodiment.

The third mode is a control mode used under a condition that the second power class is applied to Bands A and B and signals in Bands A and B are simultaneously transmitted. In the third mode, only one (filter 31) of the two transmission filters for Band A and only one (filter 33) of the two transmission filters for Band B are connected to antenna connection terminal 100 not via combiner 41A, as illustrated in FIG. 14. Specifically, terminal 511A is connected to terminal 515 and not connected to terminal 513 in switch 51A. Furthermore, terminal 512A is not connected to terminal 514.

Terminal 521 is connected to terminal 523 and not connected to terminal 522 in switch 52. Terminal 531 is connected to terminal 533 and not connected to terminal 535 in switch 53. Furthermore, terminal 532 is connected to terminal 535 and not connected to terminal 534 or 536.

Accordingly, a transmission signal in Band A received from RFIC 3 via radio frequency input terminal 111 is transferred to antenna connection terminal 100 via power amplifier 11, switch 53, filter 31, and switches 51A and 52. Furthermore, a transmission signal in Band B received from RFIC 3 via radio frequency input terminal 112 is transferred to antenna connection terminal 100 via power amplifier 12, switch 53, filter 33, and switches 51A and 52.

### [2.4 Advantageous Effects and Others]

As described above, radio frequency circuit 1A according to the present embodiment includes: filter 31 having a passband that includes a transmission band of Band A to which a plurality of power classes are applicable; filter 32 having a passband that includes the transmission band of Band A; combiner 41A that includes terminals 411 to 413; and switch 51A that includes terminals 511A, 512A, and 513 to 515. Terminal 413 of combiner 41A is connected to antenna connection terminal 100. Terminal 511A of switch 51A is connected to one end of filter 31. Terminal 512A of switch 51A is connected to one end of filter 32. Terminal 513 of switch 51A is connected to terminal 411 of combiner 41A. Terminal 514 of switch 51A is connected to terminal 412 of combiner 41A, and terminal 515 of switch 51A is connected to antenna connection terminal 100 not via combiner 41A.

According to this, two filters 31 and 32 that include a transmission band of Band A to which a plurality of power classes are applicable can be connected to antenna connection terminal 100 via combiner 41A. Thus, combiner 41A can combine two transmission signals in Band A and output the resultant signal to antenna connection terminal 100. As a result, for example, under a condition that a higher power class (Power Class 2, for example) is applied, maximum powers of transmission signals in Band A that pass through filters 31 and 32 can be decreased. Stated differently, required power durability for two filters 31 and 32 can be decreased, and higher power classes can be more readily supported. Furthermore, filters 31 and 32 can be connected to antenna connection terminal 100 not via combiner 41A. Thus, signal loss due to combiner 41A can be avoided, and power efficiency can be improved, for example, under a condition that a lower power class (Power Class 3, for example) is applied.

For example, in radio frequency circuit 1A according to the present embodiment, Band A may be a frequency division duplex (FDD) band.

According to this, an FDD band is used for Band A to which a plurality of power classes are applicable. In an FDD band, signals are continuously transmitted, and thus required power durability for a filter is higher than that in a case of a TDD band. Thus, under a condition that an FDD band is used for Band A, the effect of lowering required power durability for two filters 31 and 32 is significant.

For example, radio frequency circuit 1A according to the present embodiment may further include: power amplifier 11 connected to another end of filter 31; and power amplifier 12 connected to another end of filter 32.

According to this, two transmission signals in Band A that are amplified by two power amplifiers 11 and 12 can be combined by combiner 41A, and the resultant signal can be output to antenna connection terminal 100. Thus, required output power for power amplifiers 11 and 12 in a higher power class, for example, can be lowered. Stated differently, amplification performance that two power amplifiers 11 and 12 are to exhibit can be lowered, and higher power classes can be more readily supported.

For example, in radio frequency circuit 1A according to the present embodiment, power amplifiers 11 and 12 and combiner 41A may be included in a differential-amplifier type power amplifier, combiner 41A may be a transformer that includes primary coil L1A and secondary coil L2, and in combiner 41A, terminal 411 may be connected to one end of primary coil L1A, terminal 412 may be connected to another end of primary coil L1A, and terminal 413 may be connected to one end of secondary coil L2.

According to this, two antiphase transmission signals in Band A (that is, differential signals) can be amplified by using a differential-amplifier type amplifier circuit, and spurious emission (in particular, even-ordered harmonic distortion) can be attenuated.

For example, radio frequency circuit 1A according to the present embodiment may further include switch 52 that includes terminals 521 to 523, terminal 521 of switch 52 may be connected to antenna connection terminal 100, terminal 522 of switch 52 may be connected to terminal 413 of combiner 41A, and terminal 523 of switch 52 may be connected to terminal 515 of switch 51A.

According to this, switch 52 can switch between a path that connects two filters 31 and 32 to antenna connection terminal 100 via combiner 41A and a path that connects filter 31 or 32 to antenna connection terminal 100 not via combiner 41A. Thus, isolation between the two paths can be enhanced.

For example, radio frequency input terminal 1A according to the present embodiment may further include: filter 33 having a passband that includes a transmission band of Band B to which the plurality of power classes are applicable; filter 34 having a passband that includes the transmission band of Band B; and switch 53 that includes terminals 531 to 536. Terminal 511A of switch 51A may further be connected to one end of filter 33. Terminal 512A of switch 51A may further be connected to one end of filter 34. Terminal 531 of switch 53 may be connected to radio frequency input terminal 111. Terminal 532 of switch 53 may be connected to radio frequency input terminal 112. Terminal 533 of switch 53 may be connected to another end of filter 31. Terminal 534 of switch 53 may be connected to another end of filter 32. Terminal 535 of switch 53 may be connected to another end of filter 33, and terminal 536 of switch 53 may be connected to another end of filter 34.

According to this, similarly to Band A, also for Band B to which a plurality of power classes are applicable, a higher power class can also be more readily supported and power efficiency can be enhanced in a lower power class.

For example, radio frequency circuit 1A according to the present embodiment may have a first mode, a second mode, and a third mode. In the first mode, (i) in switch 51A, terminal 511A may be connected to terminal 513, and terminal 512A may be connected to terminal 514, (ii) in switch 52, terminal 521 may be connected to terminal 522, and (iii) in switch 53, terminal 531 may be connected to terminal 533, and terminal 532 may be connected to terminal 534. In the second mode, (i) in switch 51A, terminal 511A may be connected to terminal 513, and terminal 512A may be connected to terminal 514, (ii) in switch 52, terminal 521 may be connected to terminal 522, and (iii) in switch 53, terminal 531 may be connected to terminal 535, and terminal 532 may be connected to terminal 536, and in the third mode, (i) in switch 51A, terminal 511A may be connected to terminal 515, (ii) in switch 52, terminal 521 may be connected to terminal 523, and (iii) in switch 53, terminal 531 may be connected to terminal 533, and terminal 532 may be connected to terminal 535.

According to this, by using the first mode, two filters 31 and 32 are connected to antenna connection terminal 100 via combiner 41A. Furthermore, by using the second mode, two filters 33 and 34 are connected to antenna connection terminal 100 via combiner 41A. Moreover, by using the third mode, two filters 31 and 33 are connected to antenna connection terminal 100 not via combiner 41A.

For example, in radio frequency circuit 1A according to the present embodiment, the plurality of power classes may include a first power class and a second power class, in the first power class, a maximum output power higher than a maximum output power of the second power class may be allowed, the first mode may be used under a condition that the first power class is applied to Band A, the second mode may be used under a condition that the first power class is applied to Band B, and the third mode may be used under a condition that the second power class is applied to Band A and Band B.

According to this, by using the first mode in a higher power class (that is, the first power class), maximum powers of transmission signals in Band A that pass through filters 31 and 32 can be lowered, and required power durability for two filters 31 and 32 can be decreased. Similarly, by using the second mode in a higher power class, maximum powers of transmission signals in Band B that pass through filters 33 and 34 can be lowered, and required power durability for two filters 33 and 34 can be decreased. Furthermore, by using the third mode in a lower power class (that is, the second power class), signal loss due to combiner 41A can be avoided, and power efficiency can be improved.

### Embodiment 3

Next, Embodiment 3 is to be described. The present embodiment is mainly different from Embodiment 2 above in that a combiner is included in a radio frequency circuit for each band. In the following, the present embodiment is to be described with reference to the drawings, focusing on different points from Embodiments 1 and 2 above.

Note that a circuit configuration of communication device 5B according to the present embodiment is similar to the circuit configuration of communication device 5 according to Embodiment 1 above except that radio frequency circuit 1B is included instead of radio frequency circuit 1, and thus a description thereof is omitted.

### [3.1 Circuit Configuration of Radio Frequency Circuit 1B]

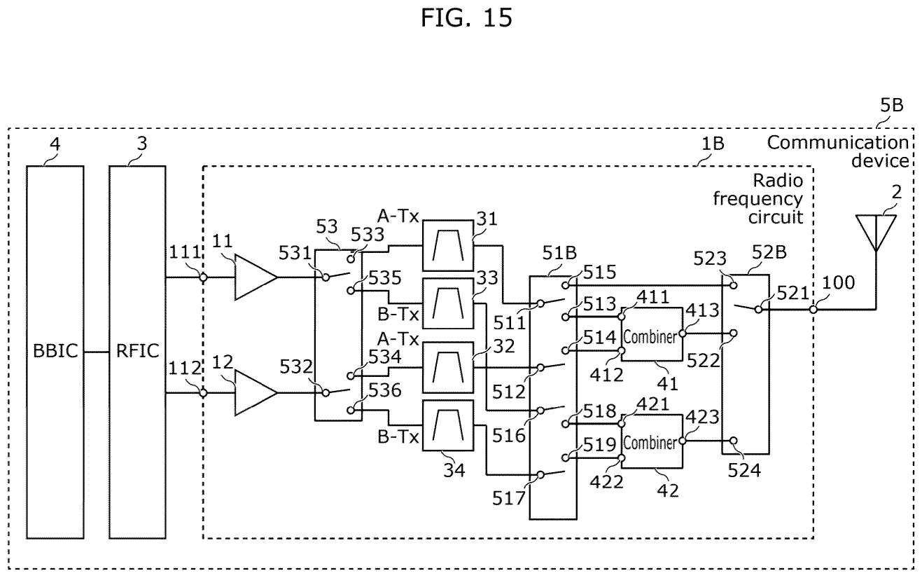

A circuit configuration of radio frequency circuit 1B is to be described with reference to FIG. 15. FIG. 15 illustrates a circuit configuration of communication device 5B according to the present embodiment.

Note that FIG. 15 illustrates an exemplary circuit configuration, and communication device 5B and radio frequency circuit 1B may be implemented using any of various types of circuit implementations and circuit technologies. Thus, the description of radio frequency circuit 1B provided below should not be interpreted in a limited manner.

Radio frequency circuit 1B includes power amplifiers 11 and 12, filters 31 to 34, combiners 41 and 42, switches 51B, 52B, and 53, antenna connection terminal 100, and radio frequency input terminals 111 and 112.

Combiner 42 is an example of a second combiner, and includes terminals 421 to 423. Terminal 421 is an example of a first input terminal, and is connected to filter 33 via switch 51B. Terminal 422 is an example of a second input terminal, and is connected to filter 34 via switch 51B. Terminal 423 is an example of an output terminal, and is connected to antenna connection terminal 100 via switch 52B.

Accordingly, combiner 42 can combine a transmission signal in Band B that has passed through filter 33 and a transmission signal in Band B that has passed through filter 34, and output the resultant signal to antenna connection terminal 100. As combiner 42, a combiner having a similar configuration to those of combiner 41 in FIG. 2 to FIG. 4 can be used. At this time, designed values of a transfer path, a resistor, a primary coil, and a secondary coil may be adjusted to those suitable for Band B.

Switch 51B is an example of a first switch, and includes terminals 511 to 519. Terminal 511 is an example of a first terminal, and is connected to one end of filter 31. Terminal 512 is an example of a second terminal, and is connected to one end of filter 32. Terminal 513 is an example of a third terminal, and is connected to terminal 411 of combiner 41. Terminal 514 is an example of a fourth terminal, and is connected to terminal 412 of combiner 41. Terminal 515 is an example of a fifth terminal, and is connected to terminal 523 of switch 52B. Terminal 516 is an example of a sixth terminal, and is connected to one end of filter 33. Terminal 517 is an example of a seventh terminal, and is connected to one end of filter 34. Terminal 518 is an example of an eighth terminal, and is connected to terminal 421 of combiner 42. Terminal 519 is an example of a ninth terminal, and is connected to terminal 422 of combiner 42.

With this connection configuration, switch 51B can (i) connect terminal 511 exclusively to terminal 513 or can connect terminal 511 exclusively to terminal 515, (ii) can connect terminal 512 to terminal 514, (iii) can connect terminal 516 exclusively to terminal 515 or can connect terminal 516 exclusively to terminal 518, and can (iv) connect terminal 517 to terminal 519, based on a control signal from RFIC 3, for example. Switch 51B includes a combination of two SPDT switch circuits and two SPST switch circuits, for example.

Switch 52B is an example of a second switch, and includes terminals 521 to 524. Terminal 521 is an example of a first terminal, and is connected to antenna connection terminal 100. Terminal 522 is an example of a second terminal, and is connected to terminal 413 of combiner 41. Terminal 523 is an example of a third terminal, and is connected to terminal 515 of switch 51B. Terminal 524 is an example of a forth terminal, and is connected to terminal 423 of combiner 42.

With this connection configuration, switch 52B can connect terminal 521 exclusively to one of terminals 522 to 524, based on a control signal from RFIC 3, for example. That is, the control signal from RFIC 3 can cause switch 52B to connect terminal 521 exclusively to terminal 522, or to connect terminal 521 exclusively to terminal 523, or to connect terminal 521 exclusively to terminal 524. Switch 52B includes an SP3T switch circuit, for example.

### [3.2 Modes of Radio Frequency Circuit 1B]

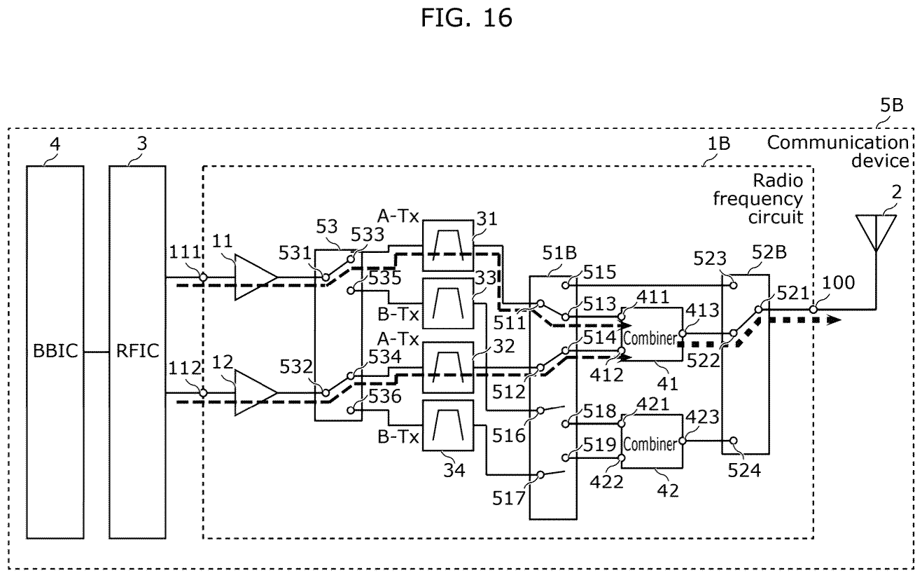

Next, a plurality of modes of radio frequency circuit 1B are to be described with reference to FIG. 16 to FIG. 18. In FIG. 16 to FIG. 18, broken-line arrows represent transmission paths.

First, a first mode of radio frequency circuit 1B is to be described with reference to FIG. 16. FIG. 16 illustrates transmission paths in the first mode of radio frequency circuit 1B according to the present embodiment.

The first mode is a control mode used under a condition that the first power class is applied to Band A and a signal in Band A is transmitted. In the first mode, two transmission filters (filters 31 and 32) for Band A are connected to antenna connection terminal 100 via combiner 41, as illustrated in FIG. 16. Specifically, terminal 511 is connected to terminal 513 and not connected to terminal 515 in switch 51B. Furthermore, terminal 512 is connected to terminal 514. Terminal 521 is connected to terminal 522 and not connected to terminal 523 or 524 in switch 52B. Terminal 531 is connected to terminal 533 and not connected to terminal 535 in switch 53. Furthermore, terminal 532 is connected to terminal 534 and not connected to terminal 535 or 536.

Accordingly, a transmission signal in Band A received from RFIC 3 via radio frequency input terminal 111 is transferred to terminal 411 of combiner 41 via power amplifier 11, switch 53, filter 31, and switch 51B. Furthermore, a transmission signal in Band A received from RFIC 3 via radio frequency input terminal 112 is transferred to terminal 412 of combiner 41 via power amplifier 12, switch 53, filter 32, and switch 51B. The two transmission signals in Band A input to terminals 411 and 412 of combiner 41 are combined into one signal, and the resultant signal is transferred to antenna connection terminal 100 via switch 52B.

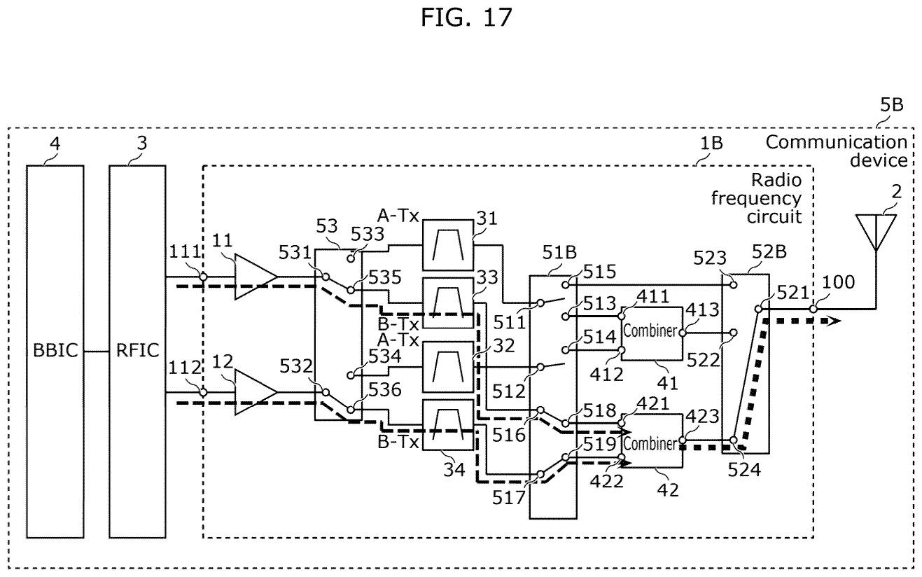

Next, a second mode of radio frequency circuit 1B is to be described with reference to FIG. 17. FIG. 17 illustrates transmission paths in the second mode of radio frequency circuit 1B according to the present embodiment.

The second mode is a control mode used under a condition that the first power class is applied to Band B and a signal in Band B is transmitted. In the second mode, two transmission filters (filters 33 and 34) for Band B are connected to combiner 42, as illustrated in FIG. 17. Specifically, terminal 516 is connected to terminal 518 and not connected to terminal 515 in switch 51B. Furthermore, terminal 517 is connected to terminal 519. Terminal 521 is connected to terminal 524 and not connected to terminal 522 or 523 in switch 52B. Terminal 531 is connected to terminal 535 and not connected to terminal 533 in switch 53. Furthermore, terminal 532 is connected to terminal 536 and not connected to terminal 534 or 535.

Accordingly, a transmission signal in Band B received from RFIC 3 via radio frequency input terminal 111 is transferred to terminal 421 of combiner 42 via power amplifier 11, switch 53, filter 33, and switch 51B. Furthermore, a transmission signal in Band B received from RFIC 3 via radio frequency input terminal 112 is transferred to terminal 422 of combiner 42 via power amplifier 12, switch 53, filter 34, and switch 51B. The two transmission signals in Band B input to terminals 421 and 422 of combiner 42 are combined into one signal, and the resultant signal is transferred to antenna connection terminal 100 via switch 52B.

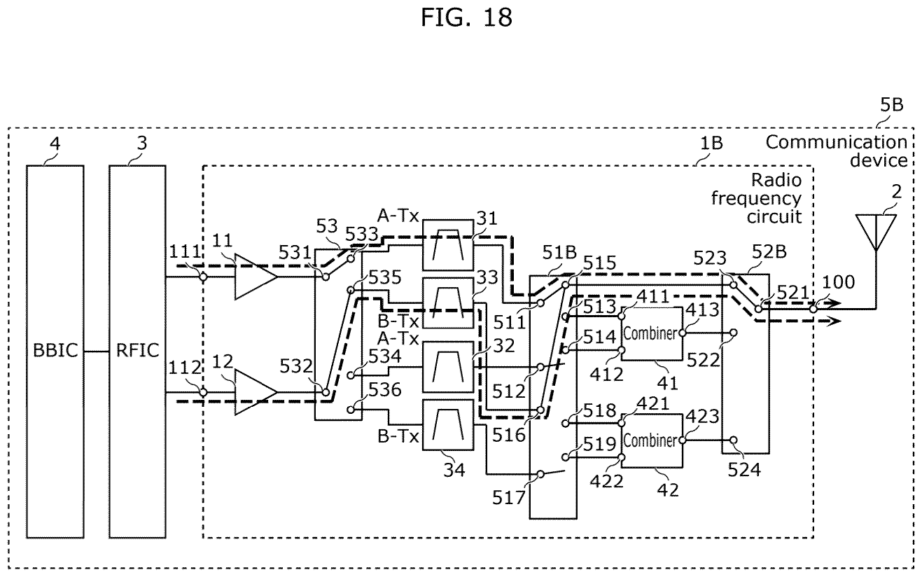

Next, a third mode of radio frequency circuit 1B is to be described with reference to FIG. 18. FIG. 18 illustrates transmission paths in the third mode of radio frequency circuit 1B according to the present embodiment.

The third mode is a control mode used under a condition that the second power class is applied to Bands A and B and signals in Bands A and B are simultaneously transmitted. In the third mode, only one (filter 31) of the two transmission filters for Band A and only one (filter 33) of the two transmission filters for Band B are connected to antenna connection terminal 100 not via combiner 41 or 42, as illustrated in FIG. 18. Specifically, terminal 511 is connected to terminal 515 and not connected to terminal 513 in switch 51B. Terminal 512 is not connected to terminal 514. Terminal 516 is connected to terminal 515 and not connected to terminal 518. Terminal 517 is not connected to terminal 519. Terminal 521 is connected to terminal 523 and not connected to terminal 522 or 524 in switch 52B. Terminal 531 is connected to terminal 533 and not connected to terminal 535 in switch 53. Furthermore, terminal 532 is connected to terminal 535 and not connected to terminal 534 or 536.

Accordingly, a transmission signal in Band A received from RFIC 3 via radio frequency input terminal 111 is transferred to antenna connection terminal 100 via power amplifier 11, switch 53, filter 31, and switches 51B and 52B. Furthermore, a transmission signal in Band B received from RFIC 3 via radio frequency input terminal 112 is transferred to antenna connection terminal 100 via power amplifier 12, switch 53, filter 33, and switches 51B and 52B.

### [3.3 Advantageous Effects and Others]

As described above, radio frequency circuit 1B according to the present embodiment includes: filter 31 having a passband that includes a transmission band of Band A to which a plurality of power classes are applicable; filter 32 having a passband that includes the transmission band of Band A; combiner 41 that includes terminals 411 to 413; and switch 51B that includes terminals 511 to 515. Terminal 413 of combiner 41 is connected to antenna connection terminal 100.

Terminal 511 of switch 51B is connected to one end of filter 31. Terminal 512 of switch 51B is connected to one end of filter 32. Terminal 513 of switch 51B is connected to terminal 411 of combiner 41. Terminal 514 of switch 51B is connected to terminal 412 of combiner 41, and terminal 515 of switch 51B is connected to antenna connection terminal 100 not via combiner 41.

According to this, two filters 31 and 32 that include a transmission band of Band A to which a plurality of power classes are applicable can be connected to antenna connection terminal 100 via combiner 41. Thus, combiner 41 can combine two transmission signals in Band A and output the resultant signal to antenna connection terminal 100. As a result, for example, under a condition that a higher power class (Power Class 2, for example) is applied, maximum powers of transmission signals in Band A that pass through filters 31 and 32 can be decreased. Stated differently, required power durability for two filters 31 and 32 can be decreased, and higher power classes can be more readily supported. Furthermore, filters 31 and 32 can be connected to antenna connection terminal 100 not via combiner 41. Thus, signal loss due to combiner 41 can be avoided, and power efficiency can be improved under a condition that a lower power class (Power Class 3, for example) is applied, for example.

For example, in radio frequency circuit 1B according to the present embodiment, Band A may be an FDD band.

According to this, an FDD band is used for Band A to which a plurality of power classes are applicable. In an FDD band, signals are continuously transmitted, and thus required power durability for a filter is higher than that in a case of a TDD band. Thus, under a condition that an FDD band is used for Band A, the effect of lowering required power durability for two filters 31 and 32 is significant.

For example, radio frequency circuit 1B according to the present embodiment may further include: power amplifier 11 connected to another end of filter 31; and power amplifier 12 connected to another end of filter 32.

According to this, two transmission signals in Band A that are amplified by two power amplifiers 11 and 12 can be combined by combiner 41, and the resultant signal can be output to antenna connection terminal 100. Thus, required output power for power amplifiers 11 and 12 in a higher power class, for example, can be lowered. Stated differently, amplification performance that two power amplifiers 11 and 12 are to exhibit can be lowered, and higher power classes can be more readily supported.

For example, in radio frequency circuit 1B according to the present embodiment, power amplifiers 11 and 12 and combiner 41 may be included in a differential-amplifier type power amplifier, combiner 41 may be a transformer that includes primary coil L1 and secondary coil L2, and in combiner 41, terminal 411 may be connected to one end of primary coil L1, terminal 412 may be connected to another end of primary coil L1, and terminal 413 may be connected to one end of secondary coil L2.

According to this, two antiphase transmission signals in Band A (that is, differential signals) can be amplified by using a differential-amplifier type amplifier circuit, and spurious emission (in particular, even-ordered harmonic distortion) can be attenuated.

For example, radio frequency circuit 1B according to the present embodiment may further include switch 52B that includes terminals 521 to 523, terminal 521 of switch 52B may be connected to antenna connection terminal 100, terminal 522 of switch 52B may be connected to terminal 413 of combiner 41, and terminal 523 of switch 52B may be connected to terminal 515 of switch 51B.

According to this, switch 52B can switch between a path that connects two filters 31 and 32 to antenna connection terminal 100 via combiner 41 and a path that connects filter 31 or 32 to antenna connection terminal 100 not via combiner 41. Thus, isolation between the two paths can be enhanced.

For example, radio frequency input terminal 1B according to the present embodiment may further include: filter 33 having a passband that includes a transmission band of Band B to which the plurality of power classes are applicable; filter 34 having a passband that includes the transmission band of Band B; switch 53 that includes terminals 531 to 536; and combiner 42 that includes terminals 421 to 423. Switch 52B may further include terminal 524. Terminal 423 of combiner 42 may be connected to antenna connection terminal 100. Switch 51B may further include terminals 516 to 519. Terminal 516 of switch 51B may be connected to one end of filter 33. Terminal 517 of switch 51B may be connected to one end of filter 34. Terminal 518 of switch 51B may be connected to terminal 421 of combiner 42. Terminal 519 of switch 51B may be connected to terminal 422 of combiner 42. Terminal 524 of switch 52B may be connected to terminal 423 of combiner 42. Terminal 531 of switch 53 may be connected to radio frequency input terminal 111. Terminal 532 of switch 53 may be connected to radio frequency input terminal 112. Terminal 533 of switch 53 may be connected to another end of filter 31. Terminal 534 of switch 53 may be connected to another end of filter 32. Terminal 535 of switch 53 may be connected to another end of filter 33, and terminal 536 of switch 53 may be connected to another end of filter 34.

According to this, similarly to Band A, also for Band B to which a plurality of power classes are applicable, a higher power class can also be more readily supported and power efficiency can be enhanced in a lower power class.

For example, radio frequency circuit 1B according to the present embodiment may have a first mode, a second mode, and a third mode. In the first mode, (i) in switch 51B, terminal 511 may be connected to terminal 513, and terminal 512 may be connected to terminal 514, (ii) in switch 52B, terminal 521 may be connected to terminal 522, and (iii) in switch 53, terminal 531 may be connected to terminal 533, and terminal 532 may be connected to terminal 534. In the second mode, (i) in switch 51B, terminal 516 may be connected to terminal 518, and terminal 517 may be connected to terminal 519, (ii) in switch 52B, terminal 521 may be connected to terminal 524, and (iii) in switch 53, terminal 531 may be connected to terminal 535, and terminal 532 may be connected to terminal 536. In the third mode, (i) in switch 51B, terminal 511 and terminal 516 may be connected to terminal 515, (ii) in switch 52B, terminal 521 may be connected to terminal 523, and (iii) in switch 53, terminal 531 may be connected to terminal 533, and terminal 532 may be connected to terminal 535.

According to this, by using the first mode, two filters 31 and 32 are connected to antenna connection terminal 100 via combiner 41. Furthermore, by using the second mode, two filters 33 and 34 are connected to antenna connection terminal 100 via combiner 42. Moreover, by using the third mode, two filters 31 and 33 are connected to antenna connection terminal 100 not via combiner 41 or 42.

For example, in radio frequency circuit 1B according to the present embodiment, the plurality of power classes may include a first power class and a second power class, in the first power class, a maximum output power higher than a maximum output power of the second power class may be allowed, the first mode may be used under a condition that the first power class is applied to Band A, the second mode may be used under a condition that the first power class is applied to Band B, and the third mode may be used under a condition that the second power class is applied to Band A and Band B.

According to this, by using the first mode in a higher power class (that is, the first power class), maximum powers of transmission signals in Band A that pass through filters 31 and 32 can be lowered, and required power durability for two filters 31 and 32 can be decreased. Similarly, by using the second mode in a higher power class, maximum powers of transmission signals in Band B that pass through filters 33 and 34 can be lowered, and required power durability for two filters 33 and 34 can be decreased. Furthermore, in a lower power class (that is, the second power class), signal loss due to combiners 41 and 42 can be avoided, and power efficiency can be improved.

### Embodiment 4

Next, Embodiment 4 is to be described. The present embodiment is mainly different from Embodiment 1 above in that in addition to transmission of signals in Band A, transmission and reception of signals in a plurality of bands to which the second power class is applied are supported. In the following, the present embodiment is to be described with reference to the drawings, focusing on different points from Embodiment 1 above.

Note that the circuit configuration of communication device 5C according to the present embodiment is similar to the circuit configuration of communication device 5 according to Embodiment 1 above except that radio frequency circuit 1C is included instead of radio frequency circuit 1, and thus a description thereof is omitted.

### [4.1 Circuit Configuration of Radio Frequency Circuit 1C]

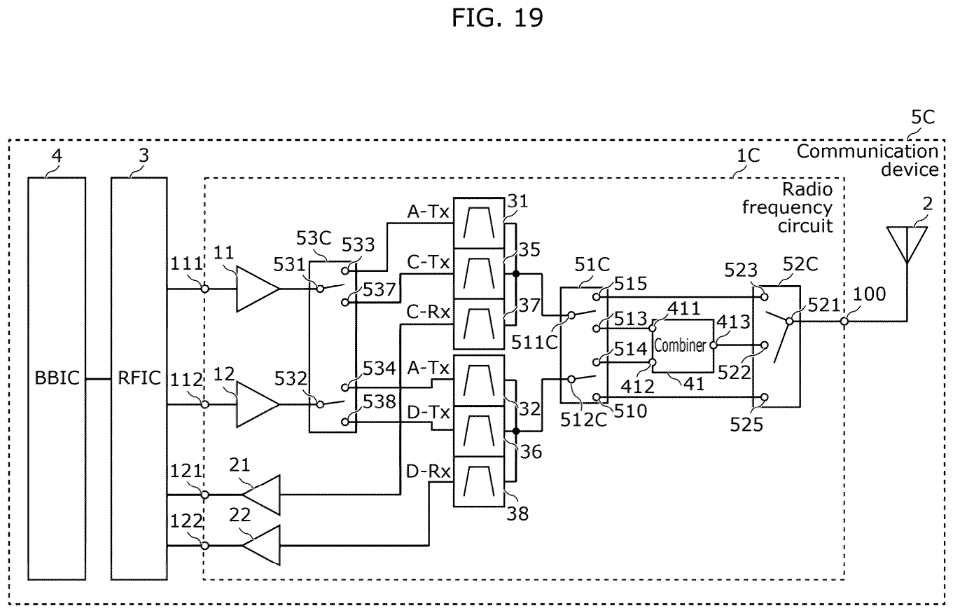

A circuit configuration of radio frequency circuit 1C is to be described with reference to FIG. 19. FIG. 19 illustrates a circuit configuration of communication device 5C according to the present embodiment.

Note that FIG. 19 illustrates an exemplary circuit configuration, and communication device 5C and radio frequency circuit 1C may be and circuit technologies. Thus, the description of radio frequency circuit 1C provided below should not be interpreted in a limited manner.

Radio frequency circuit 1C includes power amplifiers 11 and 12, low-noise amplifiers 21 and 22, filters 31, 32, and 35 to 38, combiner 41, switches 51C to 53C, antenna connection terminal 100, radio frequency input terminals 111 and 112, and radio frequency output terminals 121 and 122.

Radio frequency output terminals 121 and 122 are external connection terminals of radio frequency circuit 1C. Specifically, radio frequency output terminal 121 is connected to RFIC 3 outside radio frequency circuit 1C and is connected to low-noise amplifier 21 inside radio frequency circuit 1C. Radio frequency output terminal 122 is connected to RFIC 3 outside radio frequency circuit 1C and is connected to low-noise amplifier 22 inside radio frequency circuit 1C. Accordingly, radio frequency circuit 1C can supply RFIC 3 with radio frequency received signals via radio frequency output terminals 121 and 122.

The input end of low-noise amplifier 21 is connected to filter 37, and the output end of low-noise amplifier 21 is connected to radio frequency output terminal 121. Low-noise amplifier 21 can amplify a received signal in Band C that has passed through filter 37, by using power supplied from a power source (not illustrated).

The input end of low-noise amplifier 22 is connected to filter 38, and the output end of low-noise amplifier 22 is connected to radio frequency output terminal 122. Low-noise amplifier 22 can amplify a received signal in Band D that has passed through filter 38, by using power supplied from a power source (not illustrated).

Low-noise amplifiers 21 and 22 can include field effect transistors (FETs), and can be manufactured using a semiconductor material. As the semiconductor material, for example, monocrystal silicon, gallium nitride (GaN), or silicon carbide (SIC) can be used. Note that amplifier transistors of low-noise amplifiers 21 and 22 are not limited to FETs. For example, low-noise amplifier 21 and/or low-noise amplifier 22 may include bipolar transistors.

Note that at least one of low-noise amplifier 21 or low-noise amplifier 22 may not be included in radio frequency circuit 1C. In this case, low-noise amplifier 21 may be connected between radio frequency output terminal 121 and RFIC 3, and low-noise amplifier 22 may be connected between radio frequency output terminal 122 and RFIC 3. At least one of low-noise amplifier 21 or low-noise amplifier 22 may be included in RFIC 3.

Filter 35 is an example of a fifth filter, and is connected between antenna connection terminal 100 and radio frequency input terminal 111. Specifically, one end of filter 35 is connected to switch 51C, and another end of filter 35 is connected to switch 53C. Filter 35 is a bandpass filter having a passband that includes a transmission band of Band C. Note that filter 35 is not limited to a bandpass filter.

Filter 36 is an example of a sixth filter, and is connected between antenna connection terminal 100 and radio frequency input terminal 112. Specifically, one end of filter 36 is connected to switch 51C, and another end of filter 36 is connected to switch 53C. Filter 36 is a bandpass filter having a passband that includes a transmission band of Band D. Note that filter 36 is not limited to a bandpass filter.

Filter 37 is an example of a seventh filter, and is connected between antenna connection terminal 100 and radio frequency output terminal 121. Specifically, one end of filter 37 is connected to switch 51C, and another end of filter 37 is connected to low-noise amplifier 21. Filter 37 is a bandpass filter having a passband that includes a receiving band of Band C. Note that filter 37 is not limited to a bandpass filter.

Filter 38 is an example of an eighth filter, and is connected between antenna connection terminal 100 and radio frequency output terminal 122. Specifically, one end of filter 38 is connected to switch 51C, and another end of filter 38 is connected to low-noise amplifier 22. Filter 38 is a bandpass filter having a passband that includes a receiving band of Band C. Note that filter 38 is not limited to a bandpass filter.

A SAW filter, a BAW filter, an LC resonator filter, a dielectric resonator filter, or a combination of any of these may be used as such filters 35 to 38 similarly to filters 31 and 32, and furthermore, filters 35 to 38 are not limited to these.

Bands C and D are frequency bands for a communication system constructed by using RAT and are defined in advance by a standardizing body, for instance. As Bands C and D, FDD bands to which the second power class is applicable can be used. More specifically, Band 2, Band 4, Band 13, Band 14, Band 18, Band 20, Band 25, Band 66, or Band 70 for LTE or n2, n14, n18, n20, n25, n66, or n70 for 5G NR can be used as Bands C and D. Note that Bands C and D are not limited to the above bands and, for example, TDD bands, SUL bands, or supplementary downlink (SDL) bands may be used. For example, Band 34 or Band 39 for LTE or n34 or n39 for 5G NR may be used as Bands C and D.

Switch 51C is an example of a first switch, and includes terminals 511C, 512C, 513 to 515, and 510. Terminal 511C is an example of a first terminal, and is connected to one end of each of filters 31, 35, and 37. Terminal 512C is an example of a second terminal, and is connected to one end of each of filters 32, 36, and 38. Terminal 513 is an example of a third terminal, and is connected to terminal 411 of combiner 41. Terminal 514 is an example of a fourth terminal, and is connected to terminal 412 of combiner 41. Terminal 515 is an example of a fifth terminal, and is connected to terminal 523 of switch 52C. Terminal 510 is an example of a tenth terminal, and is connected to terminal 525 of switch 52C.

With this connection configuration, switch 51C (i) can connect terminal 511C exclusively to terminal 513 or can connect terminal 511C exclusively to terminal 515 and (ii) can connect terminal 512C exclusively to terminal 514 or can connect terminal 512C exclusively to terminal 510, based on a control signal from RFIC 3, for example. Switch 51C includes a combination of two SPDT switch circuits, for example.

Switch 52C is an example of a second switch, and includes terminals 521 to 523 and 525. Terminal 521 is an example of a first terminal, and is connected to antenna connection terminal 100. Terminal 522 is an example of a second terminal, and is connected to terminal 413 of combiner 41. Terminal 523 is an example of a third terminal, and is connected to terminal 515 of switch 51C. Terminal 525 is an example of a fifth terminal, and is connected to terminal 510 of switch 51C.

With this connection configuration, switch 52C can connect terminal 521 to terminals 522, 523, and 525, based on a control signal from RFIC 3, for example. Switch 52C includes a multi-connection type switch circuit, for example.

Switch 53C is an example of a third switch, and includes terminals 531 to 534, 537, and 538. Terminal 531 is an example of a first terminal, and is connected to the output end of power amplifier 11. Terminal 532 is an example of a second terminal, and is connected to the output end of power amplifier 12. Terminal 533 is an example of a third terminal, and is connected to another end of filter 31. Terminal 534 is an example of a fourth terminal, and is connected to another end of filter 32. Terminal 537 is an example of a seventh terminal, and is connected to another end of filter 35. Terminal 538 is an example of an eighth terminal, and is connected to another end of filter 36.

With this connection configuration, switch 53C can connect terminal 531 exclusively to terminal 533, 534, or 537 and can connect terminal 532 exclusively to terminal 534, 537, or 538, based on a control signal from RFIC 3, for example. That is, the control signal from RFIC 3 can cause switch 53C to connect terminal 531 exclusively to terminal 533, or to connect terminal 531 exclusively to terminal 534, or to connect terminal 531 exclusively to terminal 537. The control signal from RFIC 3 can also cause switch 53C to connect terminal 532 exclusively to terminal 534, or to connect terminal 532 exclusively to terminal 537, or to connect terminal 532 exclusively to terminal 538. Switch 53C includes a combination of two SP3T switch circuits, for example.

### [4.2 Modes of Radio Frequency Circuit 1C]

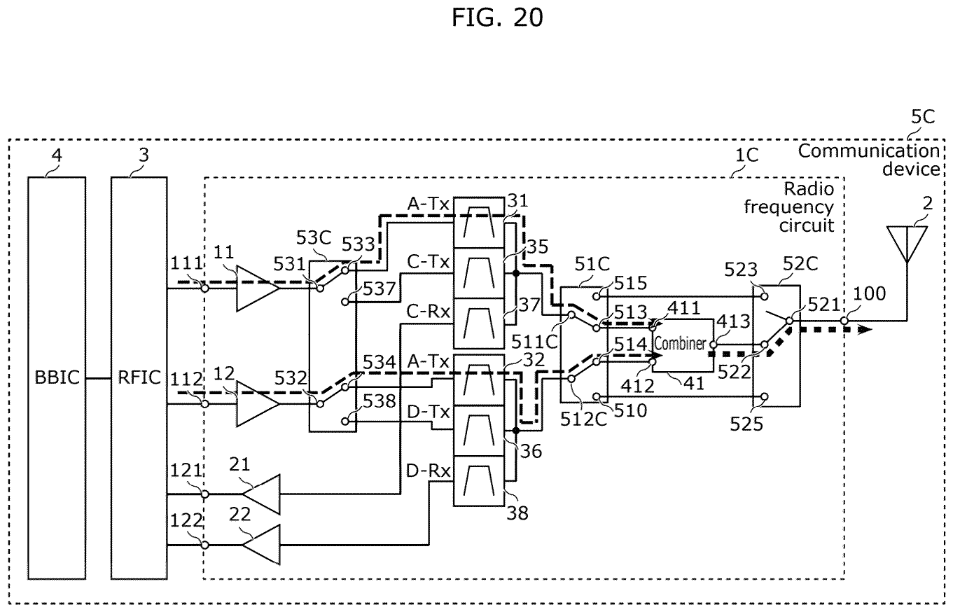

Next, a plurality of modes of radio frequency circuit 1C are to be described with reference to FIG. 20 to FIG. 23. In FIG. 20 to FIG. 23, broken-line arrows represent transmission paths and reception paths.

First, a first mode of radio frequency circuit 1C is to be described with reference to FIG. 20. FIG. 20 illustrates transmission paths in the first mode of radio frequency circuit 1C according to the present embodiment.

The first mode is a control mode used under a condition that the first power class is applied to Band A and a signal in Band A is transmitted. In the first mode, two transmission filters (filters 31 and 32) for Band A are connected to antenna connection terminal 100 via combiner 41, as illustrated in FIG. 20. Specifically, terminal 511C is connected to terminal 513 and not connected to terminal 515 in switch 51C. Furthermore, terminal 512C is connected to terminal 514 and not connected to terminal 510. Terminal 521 is connected to terminal 522 and not connected to terminal 523 or 525 in switch 52C. Terminal 531 is connected to terminal 533 and not connected to terminal 534 or 537 in switch 53C. Furthermore, terminal 532 is connected to terminal 534 and not connected to terminal 537 or 538.

Accordingly, a transmission signal in Band A received from RFIC 3 via radio frequency input terminal 111 is transferred to terminal 411 of combiner 41 via power amplifier 11, switch 53C, filter 31, and switch 51C. Furthermore, a transmission signal in Band A received from RFIC 3 via radio frequency input terminal 112 is transferred to terminal 412 of combiner 41 via power amplifier 12, switch 53C, filter 32, and switch 51C. The two transmission signals in Band A input to terminals 411 and 412 of combiner 41 are combined into one signal, and the resultant signal is transferred to antenna connection terminal 100 via switch 52C.

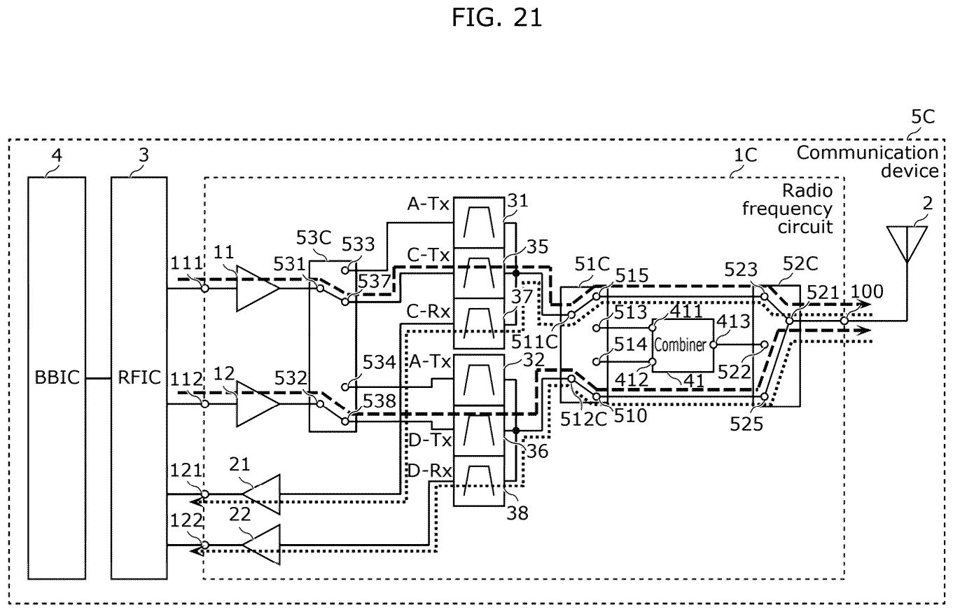

Next, a second mode of radio frequency circuit 1C is to be described with reference to FIG. 21. FIG. 21 illustrates transmission paths and reception paths in the second mode of radio frequency circuit 1C according to the present embodiment.

The second mode is a control mode used under a condition that the second power class is applied to Bands C and D and signals in Bands C and D are simultaneously transmitted, simultaneously received, and simultaneously transmitted and received. In the second mode, as illustrated in FIG. 21, transmission filters (filters 35 and 36) for Bands C and D are connected to antenna connection terminal 100 not via combiner 41, and reception filters (filters 37 and 38) for Bands C and D are connected to antenna connection terminal 100. Specifically, terminal 511C is connected to terminal 515 and not connected to terminal 513 in switch 51C. Furthermore, terminal 512C is connected to terminal 510 and not connected to terminal 514. Terminal 521 is connected to terminals 523 and 525 and not connected to terminal 522 in switch 52C. Terminal 531 is connected to terminal 537 and not connected to terminal 533 or 534 in switch 53C. Furthermore, terminal 532 is connected to terminal 538 and not connected to terminal 534 or 537.

Accordingly, a transmission signal in Band C received from RFIC 3 via radio frequency input terminal 111 is transferred to antenna connection terminal 100 via power amplifier 11, switch 53C, filter 35, and switches 51C and 52C. Furthermore, a transmission signal in Band D received from RFIC 3 via radio frequency input terminal 112 is transferred to antenna connection terminal 100 via power amplifier 12, switch 53C, filter 36, and switches 51C and 52C. Furthermore, a received signal in Band C received from antenna 2 via antenna connection terminal 100 is transferred to radio frequency output terminal 121 via switches 52C and 51C, filter 37, and low-noise amplifier 21. A received signal in Band D received from antenna 2 via antenna connection terminal 100 is transferred to radio frequency output terminal 122 via switches 52C and 51C, filter 38, and low-noise amplifier 22.

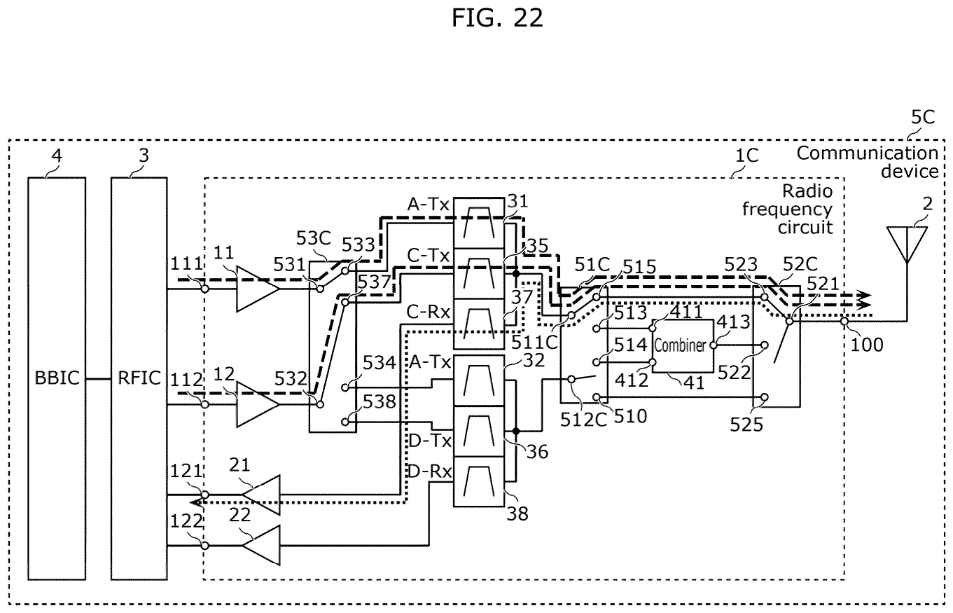

Next, a third mode of radio frequency circuit 1C is to be described with reference to FIG. 22. FIG. 22 illustrates transmission paths and a reception path in the third mode of radio frequency circuit 1C according to the present embodiment.

The third mode is a control mode used under a condition that the second power class is applied to Bands A and C and signals in Bands A and C are simultaneously transmitted and simultaneously transmitted and received. In the third mode, as illustrated in FIG. 22, transmission filters (filters 31 and 35) for Bands A and C are connected to antenna connection terminal 100 not via combiner 41, and a reception filter (filter 37) for Band C is connected to antenna connection terminal 100. Specifically, terminal 511C is connected to terminal 515 and not connected to terminal 513 in switch 51C. Furthermore, terminal 512C is not connected to terminal 514 or 510. Terminal 521 is connected to terminal 523 and not connected to terminal 522 or 525 in switch 52C. Terminal 531 is connected to terminal 533 and not connected to terminal 534 or 537 in switch 53C.

Furthermore, terminal 532 is connected to terminal 537 and not connected to terminal 534 or 538.

Accordingly, a transmission signal in Band A received from RFIC 3 via radio frequency input terminal 111 is transferred to antenna connection terminal 100 via power amplifier 11, switch 53C, filter 31, and switches 51C and 52C. Furthermore, a transmission signal in Band C received from RFIC 3 via radio frequency input terminal 112 is transferred to antenna connection terminal 100 via power amplifier 12, switch 53C, filter 35, and switches 51C and 52C. Furthermore, a received signal in Band C received from antenna 2 via antenna connection terminal 100 is transferred to radio frequency output terminal 121 via switches 52C and 51C, filter 37, and low-noise amplifier 21.

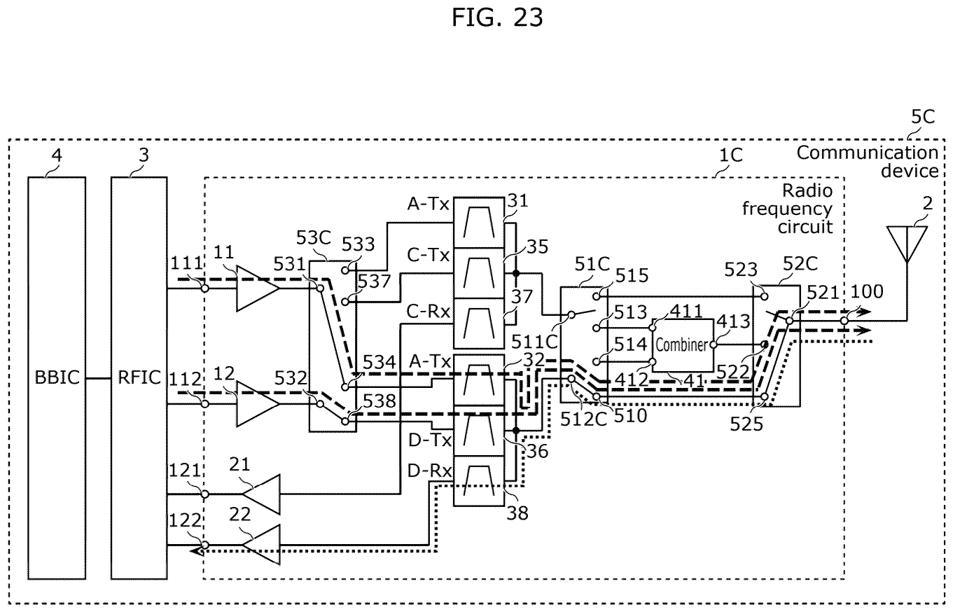

Next, a fourth mode of radio frequency circuit 1C is to be described with reference to FIG. 23. FIG. 23 illustrates transmission paths and a reception path in the fourth mode of radio frequency circuit 1C according to the present embodiment.

The fourth mode is a control mode used under a condition that the second power class is applied to Bands A and D and signals in Bands A and D are simultaneously transmitted and simultaneously transmitted and received. In the fourth mode as illustrated in FIG. 23, transmission filters (filters 32 and 36) for Bands A and D are connected to antenna connection terminal 100 not via combiner 41, and a reception filter (filter 38) for Band D is connected to antenna connection terminal 100. Specifically, terminal 512C is connected to terminal 510 and not connected to terminal 514 in switch 51C. Furthermore, terminal 511C is not connected to terminal 513 or 515. Terminal 521 is connected to terminal 525 and not connected to terminal 522 or 523 in switch 52C. Terminal 531 is connected to terminal 534 and not connected to terminal 533 or 537 in switch 53C. Furthermore, terminal 532 is connected to terminal 538 and not connected to terminal 534 or 537.

Accordingly, a transmission signal in Band A received from RFIC 3 via radio frequency input terminal 111 is transferred to antenna connection terminal 100 via power amplifier 11, switch 53C, filter 32, and switches 51C and 52C. Furthermore, a transmission signal in Band D received from RFIC 3 via radio frequency input terminal 112 is transferred to antenna connection terminal 100 via power amplifier 12, switch 53C, filter 36, and switches 51C and 52C. Furthermore, a received signal in Band D received from antenna 2 via antenna connection terminal 100 is transferred to radio frequency output terminal 122 via switches 52C and 51C, filter 38, and low-noise amplifier 22.

### [4.3 Advantageous Effects and Others]

As described above, radio frequency circuit 1C according to the present embodiment includes: filter 31 having a passband that includes a transmission band of Band A to which a plurality of power classes are applicable; filter 32 having a passband that includes the transmission band of Band A; combiner 41 that includes terminals 411 to 413; and switch 51C that includes terminal 511C, 512C, and 513 to 515. Terminal 413 of combiner 41 is connected to antenna connection terminal 100. Terminal 511C of switch 51C is connected to one end of filter 31. Terminal 512C of switch 51C is connected to one end of filter 32. Terminal 513 of switch 51C is connected to terminal 411 of combiner 41. Terminal 514 of switch 51C is connected to terminal 412 of combiner 41, and terminal 515 of switch 51C is connected to antenna connection terminal 100 not via combiner 41.

According to this, two filters 31 and 32 that include a transmission band of Band A to which a plurality of power classes are applicable can be connected to antenna connection terminal 100 via combiner 41. Thus, combiner 41 can combine two transmission signals in Band A and output the resultant signal to antenna connection terminal 100. As a result, for example, under a condition that a higher power class (Power Class 2, for example) is applied, maximum powers of transmission signals in Band A that pass through filters 31 and 32 can be decreased. Stated differently, required power durability for two filters 31 and 32 can be decreased, and higher power classes can be more readily supported. Furthermore, filters 31 and 32 can be connected to antenna connection terminal 100 not via combiner 41. Thus, signal loss due to combiner 41 can be avoided, and power efficiency can be improved under a condition that a lower power class (Power Class 3, for example) is applied, for example.

For example, in radio frequency circuit 1C according to the present embodiment, Band A may be a frequency division duplex (FDD) band.

According to this, an FDD band is used for Band A to which a plurality of power classes are applicable. In an FDD band, signals are continuously transmitted, and thus required power durability for a filter is higher than that in a case of a TDD band. Thus, under a condition that an FDD band is used for Band A, the effect of lowering required power durability for two filters 31 and 32 is significant.

For example, radio frequency circuit 1C according to the present embodiment may further include: power amplifier 11 connected to another end of filter 31; and power amplifier 12 connected to another end of filter 32.

According to this, two transmission signals in Band A that are amplified by two power amplifiers 11 and 12 can be combined by combiner 41, and the resultant signal can be output to antenna connection terminal 100. Thus, required output power for power amplifiers 11 and 12 in a higher power class, for example, can be lowered. Stated differently, amplification performance that two power amplifiers 11 and 12 are to exhibit can be lowered, and higher power classes can be more readily supported.

For example, in radio frequency circuit 1C according to the present embodiment, power amplifiers 11 and 12 and combiner 41 may be included in a differential-amplifier type power amplifier, combiner 41 may be a transformer that includes primary coil L1 and secondary coil L2, and in combiner 41, terminal 411 may be connected to one end of primary coil L1, terminal 412 may be connected to another end of primary coil L1, and terminal 413 may be connected to one end of secondary coil L2.

According to this, two antiphase transmission signals in Band A (that is, differential signals) can be amplified by using a differential-amplifier type amplifier circuit, and spurious emission (in particular, even-ordered harmonic distortion) can be attenuated.

For example, radio frequency circuit 1C according to the present embodiment may further include switch 52C that includes terminals 521 to 523, terminal 521 of switch 52C may be connected to antenna connection terminal 100, terminal 522 of switch 52C may be connected to terminal 413 of combiner 41, and terminal 523 of switch 52C may be connected to terminal 515 of switch 51C.

According to this, switch 52C can switch between a path that connects two filters 31 and 32 to antenna connection terminal 100 via combiner 41 and a path that connects filter 31 or 32 to antenna connection terminal 100 not via combiner 41. Thus, isolation between the two paths can be enhanced.

For example, radio frequency input terminal 1C according to the present embodiment may further include: filter 35 having a passband that includes a transmission band of the Band C; filter 36 having a passband that includes a transmission band of Band D; and switch 53C that includes terminals 531 to 534, 537, and 538. Switch 51C may further include terminal 510 connected to antenna connection terminal 100 not via combiner 41. Switch 52C may further include terminal 525. Terminal 511C of switch 51C may further be connected to one end of filter 35. Terminal 512C of switch 51C may further be connected to one end of filter 36. Terminal 510 of switch 51C may be connected to terminal 525 of switch 52C. Terminal 531 of switch 53C may be connected to radio frequency input terminal 111. Terminal 532 of switch 53C may be connected to radio frequency input terminal 112. Terminal 533 of switch 53C may be connected to another end of filter 31. Terminal 534 of switch 53C may be connected to another end of filter 32. Terminal 537 of switch 53C may be connected to another end of filter 35, and terminal 538 of switch 53C may be connected to another end of filter 36.

According to this, simultaneous transmission of transmission signals can be supported by a combination of any two of Bands A, C, and D.

For example, radio frequency circuit 1C according to the present embodiment may have a first mode, a second mode, a third mode, and a fourth mode. In the first mode, (i) in switch 51C, terminal 511C may be connected to terminal 513, and terminal 512C may be connected to terminal 514, (ii) in switch 52C, terminal 521 may be connected to terminal 522, and (iii) in switch 53C, terminal 531 may be connected to terminal 533, and terminal 532 may be connected to terminal 534. In the second mode, (i) in switch 51C, terminal 511C may be connected to terminal 515, and terminal 512C may be connected to terminal 510, (ii) in switch 52C, terminal 521 may be connected to terminals 523 and 525, and (iii) in switch 53C, terminal 531 may be connected to terminal 537, and terminal 532 may be connected to terminal 538. In the third mode, (i) in switch 51C, terminal 511C may be connected to terminal 515, (ii) in switch 52C, terminal 521 may be connected to terminal 523, and (iii) in switch 53C, terminal 531 may be connected to terminal 533, and terminal 532 may be connected to terminal 537. In the fourth mode, (i) in switch 51C, terminal 512C may be connected to terminal 510, (ii) in switch 52C, terminal 521 may be connected to terminal 525, and (iii) in switch 53C, terminal 531 may be connected to terminal 534, and terminal 532 may be connected to terminal 538.

According to this, by using the first mode, two filters 31 and 32 are connected to antenna connection terminal 100 via combiner 41. Furthermore, by using the second mode, two filters 35 and 36 are connected to antenna connection terminal 100 not via combiner 41. Furthermore, by using the third mode, two filters 31 and 35 are connected to antenna connection terminal 100 not via combiner 41. Moreover, by using the fourth mode, two filters 32 and 36 are connected to antenna connection terminal 100 not via combiner 41.

For example, in radio frequency circuit 1C according to the present embodiment, the plurality of power classes may include a first power class and a second power class, in the first power class, a maximum output power higher than a maximum output power of the second power class may be allowed, the first mode may be used under a condition that the first power class is applied to Band A, the second mode may be used under a condition that a signal in Band C and a signal in Band D are simultaneously transmitted, the third mode may be used under a condition that the second power class is applied to Band A and a signal in Band A and a signal in Band C are simultaneously transmitted, and the fourth mode may be used under a condition that the second power class is applied to Band A and a signal in Band A and a signal in Band D are simultaneously transmitted.

According to this, by using the first mode in a higher power class (that is, the first power class), maximum powers of transmission signals in Band A that pass through filters 31 and 32 can be lowered, and required power durability for two filters 31 and 32 can be decreased. Furthermore, by using the second to fourth modes in a lower power class (that is, the second power class), signal loss due to combiner 41 can be avoided in simultaneous transmission of signals in two bands, and power efficiency can be improved.

For example, radio frequency circuit 1C according to the present embodiment may further include: filter 37 having a passband that includes a receiving band of Band C; and eighth filter 38 having a passband that includes a receiving band of Band D. Terminal 511C of switch 51C may further be connected to one end of filter 37, and terminal 512C of switch 51C may further be connected to one end of eighth filter 38.

According to this, reception of signals in Bands C and D can be supported.

### Embodiment 5

Next, Embodiment 5 is to be described. The present embodiment is mainly different from Embodiment 1 above in that in addition to transmission of a signal in Band A, reception of a signal in Band A and transmission and reception of signals in Band C are supported. In the following, the present embodiment is to be described with reference to the drawings, focusing on different points from Embodiment 1 above.

Note that a circuit configuration of communication device 5D according to the present embodiment is similar to the circuit configuration of communication device 5 according to Embodiment 1 above except that radio frequency circuit 1D is included instead of radio frequency circuit 1, and thus a description thereof is omitted.

### [5.1 Circuit Configuration of Radio Frequency Circuit 1D]

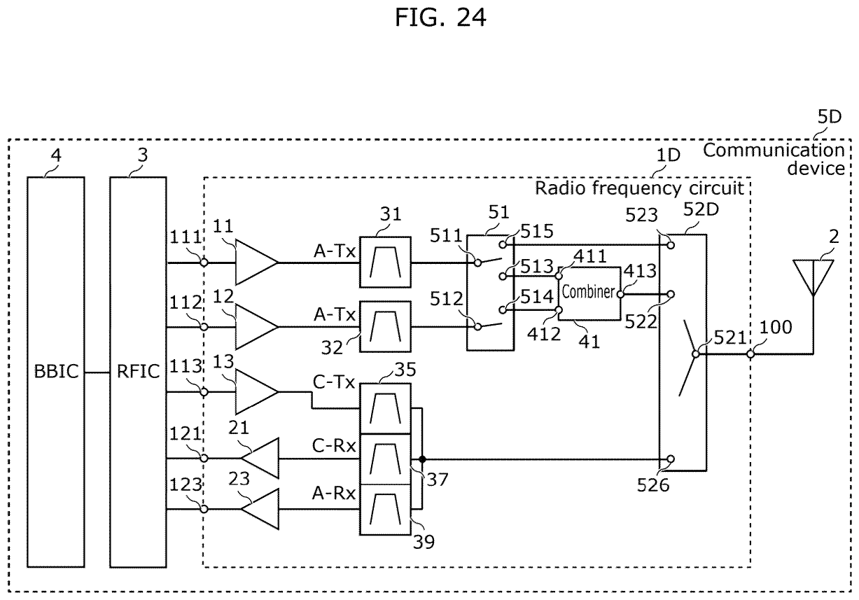

A circuit configuration of radio frequency circuit 1D is to be described with reference to FIG. 24. FIG. 24 illustrates a circuit configuration of communication device 5D according to the present embodiment.

Note that FIG. 24 illustrates an exemplary circuit configuration, and communication device 5D and radio frequency circuit 1D may be and circuit technologies. Thus, the description of radio frequency circuit 1D provided below should not be interpreted in a limited manner.

Radio frequency circuit 1D includes power amplifiers 11 to 13, low-noise amplifiers 21 and 23, filters 31, 32, 35, 37, and 39, combiner 41, switches 51 and 52D, antenna connection terminal 100, radio frequency input terminals 111 to 113, and radio frequency output terminals 121 and 123.

Radio frequency input terminal 113 is an external connection terminal of radio frequency circuit 1D. Specifically, radio frequency input terminal 113 is connected to RFIC 3 outside radio frequency circuit 1D and is connected to power amplifier 13 inside radio frequency circuit 1D. Accordingly, radio frequency circuit 1D can receive radio frequency transmission signals from RFIC 3 via radio frequency input terminal 113.

Radio frequency output terminal 123 is an external connection terminal of radio frequency circuit 1D. Specifically, radio frequency output terminal 123 is connected to RFIC 3 outside radio frequency circuit 1D and is connected to low-noise amplifier 23 inside radio frequency circuit 1D. Accordingly, radio frequency circuit 1D can supply RFIC 3 with radio frequency received signals via radio frequency output terminal 123.

The input end of power amplifier 13 is connected to radio frequency input terminal 113. The output end of power amplifier 13 is connected to filter 35. Power amplifier 13 can amplify input signals (transmission signals in Band C in the present embodiment) from radio frequency input terminal 113, by using power supplied from a power source (not illustrated). Note that power amplifier 13 can include an HBT similarly to power amplifiers 11 and 12, but is not limited thereto.

The input end of low-noise amplifier 23 is connected to filter 39, and the output end of low-noise amplifier 23 is connected to radio frequency output terminal 123. Low-noise amplifier 23 can amplify a received signal in Band A that has passed through filter 39, by using power supplied from a power source (not illustrated). Note that low-noise amplifier 23 can include an FET similarly to low-noise amplifiers 21 and 22, but is not limited thereto.

Filter 39 is an example of a ninth filter, and is connected between antenna connection terminal 100 and radio frequency output terminal 123. Specifically, one end of filter 39 is connected to switch 52D, and another end of filter 39 is connected to the input end of low-noise amplifier 23. Filter 39 is a bandpass filter having a passband that includes a receiving band of Band A. Note that filter 39 is not limited to a bandpass filter. A SAW filter, a BAW filter, an LC resonator filter, a dielectric resonator filter, or a combination of any of these may be used as filter 39 similarly to filters 31 and 32, and furthermore, filter 39 is not limited to these.

Switch 52D is an example of a second switch, and includes terminals 521 to 523 and 526. Terminal 521 is an example of a first terminal, and is connected to antenna connection terminal 100. Terminal 522 is an example of a second terminal, and is connected to terminal 413 of combiner 41. Terminal 523 is an example of a third terminal, and is connected to terminal 515 of switch 51. Terminal 526 is an example of a sixth terminal, and is connected to one end of each of filters 35, 37, and 39.

With this connection configuration, switch 52D can connect terminal 521 to terminals 522, 523, and 526, based on a control signal from RFIC 3, for example. Switch 52D includes a multi-connection type switch circuit, for example.

### [5.2 Modes of Radio Frequency Circuit 1D]

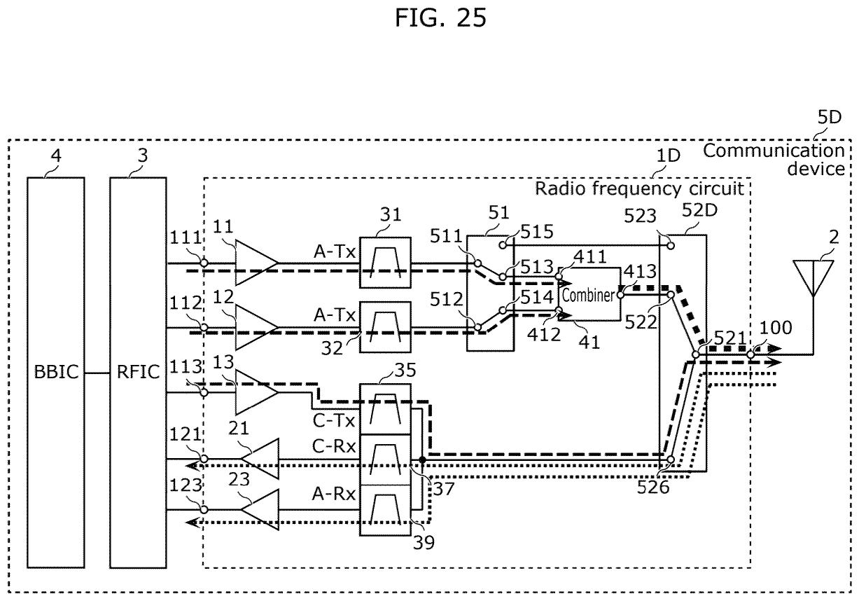

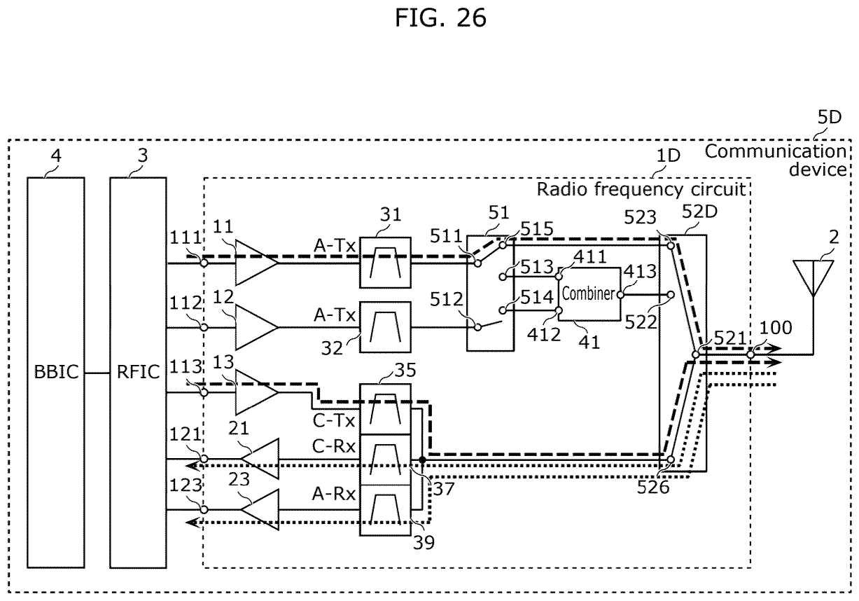

Next, a plurality of modes of radio frequency circuit 1D are to be described with reference to FIG. 25 and FIG. 26. In FIG. 25 and FIG. 26, broken-line arrows represent transmission paths and reception paths.

First, a first mode of radio frequency circuit 1D is to be described with reference to FIG. 25. FIG. 25 illustrates transmission paths in the first mode of radio frequency circuit 1D according to the present embodiment.

The first mode is a control mode used under a condition that the first power class is applied to Band A, the second power class is applied to Band C, and signals in Bands A and C are simultaneously transmitted, simultaneously received, and simultaneously transmitted and received. In the first mode, as illustrated in FIG. 25, transmission filters (filters 31 and 32) for Band A are connected to antenna connection terminal 100 via combiner 41, and a transmission filter (filter 35) for Band C and reception filters (filters 39 and 37) for Bands A and C are connected to antenna connection terminal 100. Specifically, terminal 511 is connected to terminal 513 and not connected to terminal 515 in switch 51. Furthermore, terminal 512 is connected to terminal 514. Terminal 521 is connected to terminals 522 and 526 and not connected to terminal 523 in switch 52D.

Accordingly, a transmission signal in Band A received from RFIC 3 via radio frequency input terminal 111 is transferred to terminal 411 of combiner 41 via power amplifier 11, filter 31, and switch 51. Furthermore, a transmission signal in Band A received from RFIC 3 via radio frequency input terminal 112 is transferred to terminal 412 of combiner 41 via power amplifier 12, filter 32, and switch 51. The two transmission signals in Band A input to terminals 411 and 412 of combiner 41 are combined into one signal, and the resultant signal is transferred to antenna connection terminal 100 via switch 52D. A transmission signal in Band C received from RFIC 3 via radio frequency input terminal 113 is transferred to antenna connection terminal 100 via power amplifier 13, filter 35, and switch 52D. A received signal in Band A received from antenna 2 via antenna connection terminal 100 is transferred to radio frequency output terminal 123 via switch 52D, filter 39, and low-noise amplifier 23. A received signal in Band C received from antenna 2 via antenna connection terminal 100 is transferred to radio frequency output terminal 121 via switch 52D, filter 37, and low-noise amplifier 21.

Next, a second mode of radio frequency circuit 1D is to be described with reference to FIG. 26. FIG. 26 illustrates transmission paths and reception paths in the second mode of radio frequency circuit 1D according to the present embodiment.

The second mode is a control mode used under a condition that the second power class is applied to Bands A and C and signals in Bands A and C are simultaneously transmitted, simultaneously received, and simultaneously transmitted and received. In the second mode, as illustrated in FIG. 26, only one (filter 31) of two transmission filters for Band A and a transmission filter (filter 35) for Band C are connected to antenna connection terminal 100 not via combiner 41, and reception filters (filters 39 and 37) for Bands A and C are connected to antenna connection terminal 100. Specifically, terminal 511 is connected to terminal 515 and not connected to terminal 513 in switch 51. Furthermore, terminal 512 is not connected to terminal 514. Terminal 521 is connected to terminals 523 and 526 and not connected to terminal 522 in switch 52D.

Accordingly, a transmission signal in Band A received from RFIC 3 via radio frequency input terminal 111 is transferred to antenna connection terminal 100 via power amplifier 11, filter 31, and switches 51 and 52D. A transmission signal in Band C received from RFIC 3 via radio frequency input terminal 113 is transferred to antenna connection terminal 100 via power amplifier 13, filter 35, and switch 52D. Furthermore, a received signal in Band A received from antenna 2 via antenna connection terminal 100 is transferred to radio frequency output terminal 123 via switch 52D, filter 39, and low-noise amplifier 23. Furthermore, a received signal in Band C received from antenna 2 via antenna connection terminal 100 is transferred to radio frequency output terminal 121 via switch 52D, filter 37, and low-noise amplifier 21.

### [5.3 Advantageous Effects and Others]

As described above, radio frequency circuit 1D according to the present embodiment includes: filter 31 having a passband that includes a transmission band of Band A to which a plurality of power classes are applicable; filter 32 having a passband that includes the transmission band of Band A; combiner 41 that includes terminals 411 to 413; and switch 51 that includes terminals 511 to 515. Terminal 413 of combiner 41 is connected to antenna connection terminal 100. Terminal 511 of switch 51 is connected to one end of filter 31. Terminal 512 of switch 51 is connected to one end of filter 32. Terminal 513 of switch 51 is connected to terminal 411 of combiner 41. Terminal 514 of switch 51 is connected to terminal 412 of combiner 41, and terminal 515 of switch 51 is connected to antenna connection terminal 100 not via combiner 41.

According to this, two filters 31 and 32 that include a transmission band of Band A to which a plurality of power classes are applicable can be connected to antenna connection terminal 100 via combiner 41. Thus, combiner 41 can combine two transmission signals in Band A and output the resultant signal to antenna connection terminal 100. As a result, for example, under a condition that a higher power class (Power Class 2, for example) is applied, maximum powers of transmission signals in Band A that pass through filters 31 and 32 can be decreased. Stated differently, required power durability for two filters 31 and 32 can be decreased, and higher power classes can be more readily supported. Furthermore, filters 31 and 32 may be connected to antenna connection terminal 100 not via combiner 41. Thus, signal loss due to combiner 41 can be avoided, and power efficiency can be improved, for example, under a condition that a lower power class (Power Class 3, for example) is applied.

For example, in radio frequency circuit 1D according to the present embodiment, Band A may be a frequency division duplex (FDD) band.

According to this, an FDD band is used for Band A to which a plurality of power classes are applicable. In an FDD band, signals are continuously transmitted, and thus required power durability for a filter is higher than that in a case of a TDD band. Thus, under a condition that an FDD band is used for Band A, the effect of lowering required power durability for two filters 31 and 32 is significant.

For example, radio frequency circuit 1D according to the present embodiment may further include: power amplifier 11 connected to another end of filter 31; and power amplifier 12 connected to another end of filter 32.

According to this, two transmission signals in Band A that are amplified by two power amplifiers 11 and 12 can be combined by combiner 41, and the resultant signal can be output to antenna connection terminal 100. Thus, required output power for power amplifiers 11 and 12 in a higher power class, for example, can be lowered. Stated differently, amplification performance that two power amplifiers 11 and 12 are to exhibit can be lowered, and higher power classes can be more readily supported.

For example, in radio frequency circuit 1D according to the present embodiment, power amplifiers 11 and 12, and combiner 41 may be included in a differential-amplifier type power amplifier, combiner 41 may be a transformer that includes primary coil L1 and secondary coil L2, and in combiner 41, terminal 411 may be connected to one end of primary coil L1, terminal 412 may be connected to another end of primary coil L1, and terminal 413 may be connected to one end of secondary coil L2.

According to this, two antiphase transmission signals in Band A (that is, differential signals) can be amplified by using a differential-amplifier type amplifier circuit, and spurious emission (in particular, even-ordered harmonic distortion) can be attenuated.

For example, radio frequency circuit 1D according to the present embodiment may further include switch 52D that includes terminals 521 to 523, terminal 521 of switch 52D may be connected to antenna connection terminal 100, terminal 522 of switch 52D may be connected to terminal 413 of combiner 41, and terminal 523 of switch 52D may be connected to terminal 515 of switch 51.

According to this, switch 52D can switch between a path that connects two filters 31 and 32 to antenna connection terminal 100 via combiner 41 and a path that connects filter 31 or 32 to antenna connection terminal 100 not via combiner 41. Thus, isolation between the two paths can be enhanced.

For example, radio frequency circuit 1D according to the present embodiment may further include: filter 39 having a passband that includes a receiving band of Band A. Switch 52D may further include terminal 526, and terminal 526 of switch 52D may be connected to one end of filter 39.

According to this, reception of signals in Band A can also be supported.

For example, radio frequency circuit 1D according to the present embodiment may have a first mode and a second mode, in the first mode, (i) in switch 51, terminal 511 may be connected to terminal 513 and terminal 512 may be connected to terminal 514 and (ii) in switch 52D, terminal 521 may be connected to terminals 522 and 526 of switch 52D, and in the second mode, (i) in switch 51, terminal 511 may be connected to terminal 515 and (ii) in switch 52D, terminal 521 may be connected to terminals 523 and 526 of switch 52D.

According to this, by using the first mode, two filters 31 and 32 are connected to antenna connection terminal 100 via combiner 41 and filter 39 is connected to antenna connection terminal 100. By using the second mode, filter 31 is connected to antenna connection terminal 100 not via combiner 41 and filter 39 is connected to antenna connection terminal 100.

For example, in radio frequency circuit 1D according to the present embodiment, the plurality of power classes may include a first power class and a second power class, in the first power class, a maximum output power higher than a maximum output power of the second power class may be allowed, the first mode may be used under a condition that the first power class is applied to Band A, and the second mode may be used under a condition that the second power class is applied to Band A.

According to this, by using the first mode in a higher power class (that is, the first power class), maximum powers of transmission signals in Band A that pass through filters 31 and 32 can be lowered, and required power durability for two filters 31 and 32 can be decreased. Furthermore, in a lower power class (that is, the second power class), signal loss due to combiner 41 can be avoided, and power efficiency can be improved. In both the power classes, a signal in Band A can be received while a signal in Band A is transmitted.

### OTHER EMBODIMENTS

The above has described radio frequency circuits according to the present disclosure, based on the embodiments, yet the radio frequency circuits according to the present disclosure are not limited to the above embodiments. The present disclosure also encompasses another embodiment achieved by combining arbitrary elements in the above embodiments, variations resulting from applying, to the embodiments, various modifications that may be conceived by those skilled in the art within a range that does not depart from the scope of the present disclosure, and various devices that each include the radio frequency circuit.

For example, in the circuit configurations of the radio frequency circuits according to the above embodiments, another circuit element and a line, for instance, may be provided between circuit elements and paths connecting signal paths, which are disclosed in the drawings. For example, an impedance matching circuit may be provided between a power amplifier and a filter. Furthermore, for example, an impedance matching circuit may be provided between a filter and an antenna connection terminal. An impedance matching circuit includes an inductor and/or a capacitor, for example, but is not limited to such a configuration.

Note that the variation of Embodiment 1 above may be applied to Embodiments 2 and 3 above. In this case, radio frequency circuits 1A and 1B according to Embodiments 2 and 3 may include power amplifier 11a, divider 41a, and others, instead of power amplifiers 11 and 12.

Note that two transmission signals in Band A are input from RFIC 3 to the radio frequency circuits in the embodiments above, but only one transmission signal in Band A may be input to the radio frequency circuits. In this case, a divider configured to divide one transmission signal in Band A into two signals may be included. The divider may have a similar configuration to that of a combiner. A transmission signal in Band B may also be treated in the same manner as a transmission signal in Band A.

Note that in the embodiments above, two radio frequency input terminals 111 and 112 are included for Band A, but the configuration is not limited thereto. For example, a radio frequency circuit may include only one radio frequency input terminal for Band A. In this case, a divider configured to divide a transmission signal in Band A input to the one radio frequency input terminal may be connected between the radio frequency input terminal and two power amplifiers 11 and 12.

Note that in the embodiments above, at least one of power amplifier 11 or power amplifier 12 may not be included in radio frequency circuits 1 to 1D. In this case, power amplifier 11 may be connected between RFIC 3 and radio frequency input terminal 111 outside radio frequency circuits 1 to 1D, and power amplifier 12 may be connected between RFIC 3 or another RFIC and radio frequency input terminal 112 outside radio frequency circuits 1 to 1D. At least one of power amplifier 11 or power amplifier 12 may be included in RFIC 3 or another RFIC. According to this, heat generated by radio frequency circuits 1 to 1D can be reduced, and heat dissipation of radio frequency circuits 1 to 1D can be improved.

Note that in Embodiment 5 above, power amplifier 13 may also not be included in radio frequency circuit 1D in addition to power amplifiers 11 and 12. In this case, filter 35 may also not be included in radio frequency circuit 1D. According to this, by additionally including filters 31 and 32, switch 51, and combiner 41 in a diver module that mainly includes a reception path, a higher power class (Power Class 2, for example) can be supported, and an increase in the size of the diver module can be reduced.

The following states features of the radio frequency circuits described based on the above embodiments.

<1> A radio frequency circuit including:
a first filter having a passband that includes a transmission band of a first band to which a plurality of power classes are applicable;
a second filter having a passband that includes the transmission band of the first band;
a first combiner that includes a first input terminal, a second input terminal, and an output terminal; and
a first switch that includes a first terminal, a second terminal, a third terminal, a fourth terminal, and a fifth terminal,
wherein the output terminal of the first combiner is connected to an antenna connection terminal,
the first terminal of the first switch is connected to one end of the first filter,
the second terminal of the first switch is connected to one end of the second filter,
the third terminal of the first switch is connected to the first input terminal of the first combiner,
the fourth terminal of the first switch is connected to the second input terminal of the first combiner, and
the fifth terminal of the first switch is connected to the antenna connection terminal not via the first combiner.
<2> The radio frequency circuit according to <1>, wherein the first band is a frequency division duplex band.
<3> The radio frequency circuit according to <1> or <2> further including:
a first power amplifier connected to an other end of the first filter; and
a second power amplifier connected to an other end of the second filter.
<4> The radio frequency circuit according to <3>,
wherein the first power amplifier, the second power amplifier, and the first combiner are included in a differential-amplifier type power amplifier,
the first combiner is a transformer that includes a primary coil and a secondary coil, and
in the first combiner, the first input terminal is connected to one end of the primary coil, the second input terminal is connected to an other end of the primary coil, and the output terminal is connected to one end of the secondary coil.
<5> The radio frequency circuit according to any one of <1> to <4>, further including:
a second switch that includes a first terminal, a second terminal, and a third terminal,
wherein the first terminal of the second switch is connected to the antenna connection terminal,
the second terminal of the second switch is connected to the output terminal of the first combiner, and
the third terminal of the second switch is connected to the fifth terminal of the first switch.
<6> The radio frequency circuit according to <5>,
wherein the radio frequency circuit has a first mode and a second mode,
in the first mode, (i) in the first switch, the first terminal of the first switch is connected to the third terminal of the first switch, and
the second terminal of the first switch is connected to the fourth terminal of the first switch, and (ii) in the second switch, the first terminal of the second switch is connected to the second terminal of the second switch, and
in the second mode, (i) in the first switch, the first terminal of the first switch is connected to the fifth terminal of the first switch, and (ii) in the second switch, the first terminal of the second switch is connected to the third terminal of the second switch.
<7> The radio frequency circuit according to <6>,
wherein the plurality of power classes include a first power class and a second power class,
in the first power class, a maximum output power higher than a maximum output power of the second power class is allowed,
the first mode is used under a condition that the first power class is applied to the first band, and
the second mode is used under a condition that the second power class is applied to the first band.
<8> The radio frequency circuit according to <6>,
wherein the plurality of power classes include a first power class and a second power class,
in the first power class, a maximum output power higher than a maximum output power of the second power class is allowed, the first mode is used under a condition that the first power class is applied to the first band or signal quality is prioritized over power efficiency in transmitting a signal in the first band, and
the second mode is used under a condition that the second power class is applied to the first band and power efficiency is prioritized over signal quality in transmitting a signal in the first band.
<9> The radio frequency circuit according to claim <5>, further including:
a third filter having a passband that includes a transmission band of a second band to which the plurality of power classes are applicable;
a fourth filter having a passband that includes the transmission band of the second band; and
a third switch that includes a first terminal, a second terminal, a third terminal, a fourth terminal, a fifth terminal, and a sixth terminal,
wherein the first terminal of the first switch is further connected to one end of the third filter,
the second terminal of the first switch is further connected to one end of the fourth filter,
the first terminal of the third switch is connected to a first radio frequency input terminal,
the second terminal of the third switch is connected to a second radio frequency input terminal,
the third terminal of the third switch is connected to an other end of the first filter,
the fourth terminal of the third switch is connected to an other end of the second filter,
the fifth terminal of the third switch is connected to an other end of the third filter, and
the sixth terminal of the third switch is connected to an other end of the fourth filter.
<10> The radio frequency circuit according to <9>,
wherein the radio frequency circuit has a first mode, a second mode, and a third mode,
in the first mode, (i) in the first switch, the first terminal of the first switch is connected to the third terminal of the first switch, and the second terminal of the first switch is connected to the fourth terminal of the first switch, (ii) in the second switch, the first terminal of the second switch is connected to the second terminal of the second switch, and (iii) in the third switch, the first terminal of the third switch is connected to the third terminal of the third switch, and the second terminal of the third switch is connected to the fourth terminal of the third switch,
in the second mode, (i) in the first switch, the first terminal of the first switch is connected to the third terminal of the first switch, and the second terminal of the first switch is connected to the fourth terminal of the first switch, (ii) in the second switch, the first terminal of the second switch is connected to the second terminal of the second switch, and (iii) in the third switch, the first terminal of the third switch is connected to the fifth terminal of the third switch, and the second terminal of the third switch is connected to the sixth terminal of the third switch, and
in the third mode, (i) in the first switch, the first terminal of the first switch is connected to the fifth terminal of the first switch, (ii) in the second switch, the first terminal of the second switch is connected to the third terminal of the second switch, and (iii) in the third switch, the first terminal of the third switch is connected to the third terminal of the third switch, and the second terminal of the third switch is connected to the fifth terminal of the third switch.
<11> The radio frequency circuit according to <10>,
wherein the plurality of power classes include a first power class and a second power class,
in the first power class, a maximum output power higher than a maximum output power of the second power class is allowed,
the first mode is used under a condition that the first power class is applied to the first band,
the second mode is used under a condition that the first power class is applied to the second band, and
the third mode is used under a condition that the second power class is applied to the first band and the second band.
<12> The radio frequency circuit according to <5>, further including:
a third filter having a passband that includes a transmission band of a second band to which the plurality of power classes are applicable;
a fourth filter having a passband that includes the transmission band of the second band;
a third switch that includes a first terminal, a second terminal, a third terminal, a fourth terminal, a fifth terminal, and a sixth terminal; and
a second combiner that includes a first input terminal, a second input terminal, and an output terminal,
wherein the second switch further includes a fourth terminal,
the output terminal of the second combiner is connected to the antenna connection terminal,
the first switch further includes a sixth terminal, a seventh terminal, an eighth terminal, and a ninth terminal,
the sixth terminal of the first switch is connected to one end of the third filter,
the seventh terminal of the first switch is connected to one end of the fourth filter,
the eighth terminal of the first switch is connected to the first input terminal of the second combiner,
the ninth terminal of the first switch is connected to the second input terminal of the second combiner,
the fourth terminal of the second switch is connected to the output terminal of the second combiner,
the first terminal of the third switch is connected to a first radio frequency input terminal,
the second terminal of the third switch is connected to a second radio frequency input terminal,
the third terminal of the third switch is connected to an other end of the first filter,
the fourth terminal of the third switch is connected to an other end of the second filter,
the fifth terminal of the third switch is connected to an other end of the third filter, and
the sixth terminal of the third switch is connected to an other end of the fourth filter.
<13> The radio frequency circuit according to <12>,
wherein the radio frequency circuit has a first mode, a second mode, and a third mode,
in the first mode, (i) in the first switch, the first terminal of the first switch is connected to the third terminal of the first switch, and the second terminal of the first switch is connected to the fourth terminal of the first switch, (ii) in the second switch, the first terminal of the second switch is connected to the second terminal of the second switch, and (iii) in the third switch, the first terminal of the third switch is connected to the third terminal of the third switch, and the second terminal of the third switch is connected to the fourth terminal of the third switch,
in the second mode, (i) in the first switch, the sixth terminal of the first switch is connected to the eighth terminal of the first switch, and the seventh terminal of the first switch is connected to the ninth terminal of the first switch, (ii) in the second switch, the first terminal of the second switch is connected to the fourth terminal of the second switch, and (iii) in the third switch, the first terminal of the third switch is connected to the fifth terminal of the third switch, and the second terminal of the third switch is connected to the sixth terminal of the third switch, and
in the third mode, (i) in the first switch, the first terminal and the sixth terminal of the first switch are connected to the fifth terminal of the first switch, (ii) in the second switch, the first terminal of the second switch is connected to the third terminal of the second switch, and (iii) in the third switch, the first terminal of the third switch is connected to the third terminal of the third switch, and the second terminal of the third switch is connected to the fifth terminal of the third switch.
<14> The radio frequency circuit according to <13>,
wherein the plurality of power classes include a first power class and a second power class,
in the first power class, a maximum output power higher than a maximum output power of the second power class is allowed,
the first mode is used under a condition that the first power class is applied to the first band,
the second mode is used under a condition that the first power class is applied to the second band, and
the third mode is used under a condition that the second power class is applied to the first band and the second band.
<15> The radio frequency circuit according to <5>, further including:
a fifth filter having a passband that includes a transmission band of a third band;
a sixth filter having a passband that includes a transmission band of a fourth band; and
a third switch that includes a first terminal, a second terminal, a third terminal, a fourth terminal, a seventh terminal, and an eighth terminal,
wherein the first switch further includes a tenth terminal connected to the antenna connection terminal not via the first combiner,
the second switch further includes a fifth terminal,
the first terminal of the first switch is further connected to one end of the fifth filter,
the second terminal of the first switch is further connected to one end of the sixth filter,
the tenth terminal of the first switch is connected to the fifth terminal of the second switch,
the first terminal of the third switch is connected to a first radio frequency input terminal,
the second terminal of the third switch is connected to a second radio frequency input terminal,
the third terminal of the third switch is connected to an other end of the first filter,
the fourth terminal of the third switch is connected to an other end of the second filter,
the seventh terminal of the third switch is connected to an other end of the fifth filter, and
the eighth terminal of the third switch is connected to an other end of the sixth filter.
<16> The radio frequency circuit according to <15>,
wherein the radio frequency circuit has a first mode, a second mode, a third mode, and a fourth mode,
in the first mode, (i) in the first switch, the first terminal of the first switch is connected to the third terminal of the first switch, and
the second terminal of the first switch is connected to the fourth terminal of the first switch, (ii) in the second switch, the first terminal of the second switch is connected to the second terminal of the second switch, and (iii) in the third switch, the first terminal of the third switch is connected to the third terminal of the third switch, and the second terminal of the third switch is connected to the fourth terminal of the third switch,
in the second mode, (i) in the first switch, the first terminal of the first switch is connected to the fifth terminal of the first switch, and the second terminal of the first switch is connected to the tenth terminal of the first switch, (ii) in the second switch, the first terminal of the second switch is connected to the third terminal and the fifth terminal of the second switch, and (iii) in the third switch, the first terminal of the third switch is connected to the seventh terminal of the third switch, and the second terminal of the third switch is connected to the eighth terminal of the third switch,
in the third mode, (i) in the first switch, the first terminal of the first switch is connected to the fifth terminal of the first switch, (ii) in the second switch, the first terminal of the second switch is connected to the third terminal of the second switch, and (iii) in the third switch, the first terminal of the third switch is connected to the third terminal of the third switch, and the second terminal of the third switch is connected to the seventh terminal of the third switch, and
in the fourth mode, (i) in the first switch, the second terminal of the first switch is connected to the tenth terminal of the first switch, (ii) in the second switch, the first terminal of the second switch is connected to the fifth terminal of the second switch, and (iii) in the third switch, the first terminal of the third switch is connected to the fourth terminal of the third switch, and the second terminal of the third switch is connected to the eighth terminal of the third switch.
<17> The radio frequency circuit according to claim <16>,
wherein the plurality of power classes include a first power class and a second power class,
in the first power class, a maximum output power higher than a maximum output power of the second power class is allowed,
the first mode is used under a condition that the first power class is applied to the first band,
the second mode is used under a condition that a signal in the third band and a signal in the fourth band are simultaneously transmitted,
the third mode is used under a condition that the second power class is applied to the first band and a signal in the first band and a signal in the third band are simultaneously transmitted, and
the fourth mode is used under a condition that the second power class is applied to the first band and a signal in the first band and a signal in the fourth band are simultaneously transmitted.
<18> The radio frequency circuit according to any one of <15> to <17>, further including:
a seventh filter having a passband that includes a receiving band of the third band; and
an eighth filter having a passband that includes a receiving band of the fourth band,
wherein the first terminal of the first switch is further connected to one end of the seventh filter, and
the second terminal of the first switch is further connected to one end of the eighth filter.
<19> The radio frequency circuit according to <5>, further including:
a ninth filter having a passband that includes a receiving band of the first band,
wherein the second switch further includes a sixth terminal, and
the sixth terminal of the second switch is connected to one end of the ninth filter.
<20> The radio frequency circuit according to claim <19>,
wherein the radio frequency circuit has a first mode and a second mode,
in the first mode, (i) in the first switch, the first terminal of the first switch is connected to the third terminal of the first switch, and the second terminal of the first switch is connected to the fourth terminal of the first switch, and (ii) in the second switch, the first terminal of the second switch is connected to the second terminal and the sixth terminal of the second switch, and
in the second mode, (i) in the first switch, the first terminal of the first switch is connected to the fifth terminal of the first switch, and (ii) in the second switch, the first terminal of the second switch is connected to the third terminal and the sixth terminal of the second switch.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is widely applicable to communication devices such as mobile phones as radio frequency circuits disposed in front end portions.

1. A radio frequency circuit comprising:
a first filter having a passband that includes a transmission band of a first band to which a plurality of power classes are applicable;
a second filter having a passband that includes the transmission band of the first band;
a first combiner that includes a first input terminal, a second input terminal, and an output terminal; and
a first switch that includes a first terminal, a second terminal, a third terminal, a fourth terminal, and a fifth terminal,
wherein the output terminal of the first combiner is connected to an antenna connection terminal,
the first terminal of the first switch is connected to one end of the first filter,
the second terminal of the first switch is connected to one end of the second filter,
the third terminal of the first switch is connected to the first input terminal of the first combiner,
the fourth terminal of the first switch is connected to the second input terminal of the first combiner, and
the fifth terminal of the first switch is connected to the antenna connection terminal not via the first combiner.

2. The radio frequency circuit according to claim 1,
wherein the first band is a frequency division duplex band.

3. The radio frequency circuit according to claim 1, further comprising:
a first power amplifier connected to an other end of the first filter; and
a second power amplifier connected to an other end of the second filter.

4. The radio frequency circuit according to claim 3,
wherein the first power amplifier, the second power amplifier, and the first combiner are included in a differential-amplifier type power amplifier,
the first combiner is a transformer that includes a primary coil and a secondary coil, and
in the first combiner, the first input terminal is connected to one end of the primary coil, the second input terminal is connected to an other end of the primary coil, and the output terminal is connected to one end of the secondary coil.

5. The radio frequency circuit according to claim 1, further comprising:
a second switch that includes a first terminal, a second terminal, and a third terminal,
wherein the first terminal of the second switch is connected to the antenna connection terminal,
the second terminal of the second switch is connected to the output terminal of the first combiner, and
the third terminal of the second switch is connected to the fifth terminal of the first switch.

6. The radio frequency circuit according to claim 5,
wherein the radio frequency circuit has a first mode and a second mode,
in the first mode, (i) in the first switch, the first terminal of the first switch is connected to the third terminal of the first switch, and the second terminal of the first switch is connected to the fourth terminal of the first switch, and (ii) in the second switch, the first terminal of the second switch is connected to the second terminal of the second switch, and
in the second mode, (i) in the first switch, the first terminal of the first switch is connected to the fifth terminal of the first switch, and (ii) in the second switch, the first terminal of the second switch is connected to the third terminal of the second switch.

7. The radio frequency circuit according to claim 6,
wherein the plurality of power classes include a first power class and a second power class,
in the first power class, a maximum output power higher than a maximum output power of the second power class is allowed,
the first mode is used under a condition that the first power class is applied to the first band, and
the second mode is used under a condition that the second power class is applied to the first band.

8. The radio frequency circuit according to claim 6,
wherein the plurality of power classes include a first power class and a second power class,
in the first power class, a maximum output power higher than a maximum output power of the second power class is allowed,
the first mode is used under a condition that the first power class is applied to the first band or signal quality is prioritized over power efficiency in transmitting a signal in the first band, and
the second mode is used under a condition that the second power class is applied to the first band and power efficiency is prioritized over signal quality in transmitting a signal in the first band.

9. The radio frequency circuit according to claim 5, further comprising:
a third filter having a passband that includes a transmission band of a second band to which the plurality of power classes are applicable;
a fourth filter having a passband that includes the transmission band of the second band; and
a third switch that includes a first terminal, a second terminal, a third terminal, a fourth terminal, a fifth terminal, and a sixth terminal,
wherein the first terminal of the first switch is further connected to one end of the third filter,
the second terminal of the first switch is further connected to one end of the fourth filter,
the first terminal of the third switch is connected to a first radio frequency input terminal,
the second terminal of the third switch is connected to a second radio frequency input terminal,
the third terminal of the third switch is connected to an other end of the first filter,
the fourth terminal of the third switch is connected to an other end of the second filter,
the fifth terminal of the third switch is connected to an other end of the third filter, and
the sixth terminal of the third switch is connected to an other end of the fourth filter.

10. The radio frequency circuit according to claim 9,
wherein the radio frequency circuit has a first mode, a second mode, and a third mode,
in the first mode, (i) in the first switch, the first terminal of the first switch is connected to the third terminal of the first switch, and the second terminal of the first switch is connected to the fourth terminal of the first switch, (ii) in the second switch, the first terminal of the second switch is connected to the second terminal of the second switch, and (iii) in the third switch, the first terminal of the third switch is connected to the third terminal of the third switch, and the second terminal of the third switch is connected to the fourth terminal of the third switch,
in the second mode, (i) in the first switch, the first terminal of the first switch is connected to the third terminal of the first switch, and the second terminal of the first switch is connected to the fourth terminal of the first switch, (ii) in the second switch, the first terminal of the second switch is connected to the second terminal of the second switch, and (iii) in the third switch, the first terminal of the third switch is connected to the fifth terminal of the third switch, and the second terminal of the third switch is connected to the sixth terminal of the third switch, and
in the third mode, (i) in the first switch, the first terminal of the first switch is connected to the fifth terminal of the first switch, (ii) in the second switch, the first terminal of the second switch is connected to the third terminal of the second switch, and (iii) in the third switch, the first terminal of the third switch is connected to the third terminal of the third switch, and the second terminal of the third switch is connected to the fifth terminal of the third switch.

11. The radio frequency circuit according to claim 10,
wherein the plurality of power classes include a first power class and a second power class,
in the first power class, a maximum output power higher than a maximum output power of the second power class is allowed,
the first mode is used under a condition that the first power class is applied to the first band,
the second mode is used under a condition that the first power class is applied to the second band, and
the third mode is used under a condition that the second power class is applied to the first band and the second band.

12. The radio frequency circuit according to claim 5, further comprising:
a third filter having a passband that includes a transmission band of a second band to which the plurality of power classes are applicable;
a fourth filter having a passband that includes the transmission band of the second band;
a third switch that includes a first terminal, a second terminal, a third terminal, a fourth terminal, a fifth terminal, and a sixth terminal; and
a second combiner that includes a first input terminal, a second input terminal, and an output terminal,
wherein the second switch further includes a fourth terminal,
the output terminal of the second combiner is connected to the antenna connection terminal,
the first switch further includes a sixth terminal, a seventh terminal, an eighth terminal, and a ninth terminal,
the sixth terminal of the first switch is connected to one end of the third filter,
the seventh terminal of the first switch is connected to one end of the fourth filter,
the eighth terminal of the first switch is connected to the first input terminal of the second combiner,
the ninth terminal of the first switch is connected to the second input terminal of the second combiner,
the fourth terminal of the second switch is connected to the output terminal of the second combiner,
the first terminal of the third switch is connected to a first radio frequency input terminal,
the second terminal of the third switch is connected to a second radio frequency input terminal,
the third terminal of the third switch is connected to an other end of the first filter,
the fourth terminal of the third switch is connected to an other end of the second filter,
the fifth terminal of the third switch is connected to an other end of the third filter, and
the sixth terminal of the third switch is connected to an other end of the fourth filter.

13. The radio frequency circuit according to claim 12,
wherein the radio frequency circuit has a first mode, a second mode, and a third mode,
in the first mode, (i) in the first switch, the first terminal of the first switch is connected to the third terminal of the first switch, and the second terminal of the first switch is connected to the fourth terminal of the first switch, (ii) in the second switch, the first terminal of the second switch is connected to the second terminal of the second switch, and (iii) in the third switch, the first terminal of the third switch is connected to the third terminal of the third switch, and the second terminal of the third switch is connected to the fourth terminal of the third switch,
in the second mode, (i) in the first switch, the sixth terminal of the first switch is connected to the eighth terminal of the first switch, and the seventh terminal of the first switch is connected to the ninth terminal of the first switch, (ii) in the second switch, the first terminal of the second switch is connected to the fourth terminal of the second switch, and (iii) in the third switch, the first terminal of the third switch is connected to the fifth terminal of the third switch, and the second terminal of the third switch is connected to the sixth terminal of the third switch, and
in the third mode, (i) in the first switch, the first terminal and the sixth terminal of the first switch are connected to the fifth terminal of the first switch, (ii) in the second switch, the first terminal of the second switch is connected to the third terminal of the second switch, and (iii) in the third switch, the first terminal of the third switch is connected to the third terminal of the third switch, and the second terminal of the third switch is connected to the fifth terminal of the third switch.

14. The radio frequency circuit according to claim 13,
wherein the plurality of power classes include a first power class and a second power class,
in the first power class, a maximum output power higher than a maximum output power of the second power class is allowed,
the first mode is used under a condition that the first power class is applied to the first band,
the second mode is used under a condition that the first power class is applied to the second band, and
the third mode is used under a condition that the second power class is applied to the first band and the second band.

15. The radio frequency circuit according to claim 5, further comprising:
a fifth filter having a passband that includes a transmission band of a third band;
a sixth filter having a passband that includes a transmission band of a fourth band; and
a third switch that includes a first terminal, a second terminal, a third terminal, a fourth terminal, a seventh terminal, and an eighth terminal,
wherein the first switch further includes a tenth terminal connected to the antenna connection terminal not via the first combiner,
the second switch further includes a fifth terminal,
the first terminal of the first switch is further connected to one end of the fifth filter,
the second terminal of the first switch is further connected to one end of the sixth filter,
the tenth terminal of the first switch is connected to the fifth terminal of the second switch,
the first terminal of the third switch is connected to a first radio frequency input terminal,
the second terminal of the third switch is connected to a second radio frequency input terminal,
the third terminal of the third switch is connected to an other end of the first filter,
the fourth terminal of the third switch is connected to an other end of the second filter,
the seventh terminal of the third switch is connected to an other end of the fifth filter, and
the eighth terminal of the third switch is connected to an other end of the sixth filter.

16. The radio frequency circuit according to claim 15,
wherein the radio frequency circuit has a first mode, a second mode, a third mode, and a fourth mode,
in the first mode, (i) in the first switch, the first terminal of the first switch is connected to the third terminal of the first switch, and the second terminal of the first switch is connected to the fourth terminal of the first switch, (ii) in the second switch, the first terminal of the second switch is connected to the second terminal of the second switch, and (iii) in the third switch, the first terminal of the third switch is connected to the third terminal of the third switch, and the second terminal of the third switch is connected to the fourth terminal of the third switch,
in the second mode, (i) in the first switch, the first terminal of the first switch is connected to the fifth terminal of the first switch, and the second terminal of the first switch is connected to the tenth terminal of the first switch, (ii) in the second switch, the first terminal of the second switch is connected to the third terminal and the fifth terminal of the second switch, and (iii) in the third switch, the first terminal of the third switch is connected to the seventh terminal of the third switch, and the second terminal of the third switch is connected to the eighth terminal of the third switch,
in the third mode, (i) in the first switch, the first terminal of the first switch is connected to the fifth terminal of the first switch, (ii) in the second switch, the first terminal of the second switch is connected to the third terminal of the second switch, and (iii) in the third switch, the first terminal of the third switch is connected to the third terminal of the third switch, and the second terminal of the third switch is connected to the seventh terminal of the third switch, and
in the fourth mode, (i) in the first switch, the second terminal of the first switch is connected to the tenth terminal of the first switch, (ii) in the second switch, the first terminal of the second switch is connected to the fifth terminal of the second switch, and (iii) in the third switch, the first terminal of the third switch is connected to the fourth terminal of the third switch, and the second terminal of the third switch is connected to the eighth terminal of the third switch.

17. The radio frequency circuit according to claim 16,
wherein the plurality of power classes include a first power class and a second power class,
in the first power class, a maximum output power higher than a maximum output power of the second power class is allowed,
the first mode is used under a condition that the first power class is applied to the first band,
the second mode is used under a condition that a signal in the third band and a signal in the fourth band are simultaneously transmitted,
the third mode is used under a condition that the second power class is applied to the first band and a signal in the first band and a signal in the third band are simultaneously transmitted, and
the fourth mode is used under a condition that the second power class is applied to the first band and a signal in the first band and a signal in the fourth band are simultaneously transmitted.

18. The radio frequency circuit according to claim 15, further comprising:
a seventh filter having a passband that includes a receiving band of the third band; and
an eighth filter having a passband that includes a receiving band of the fourth band,
wherein the first terminal of the first switch is further connected to one end of the seventh filter, and
the second terminal of the first switch is further connected to one end of the eighth filter.

19. The radio frequency circuit according to claim 5, further comprising:
a ninth filter having a passband that includes a receiving band of the first band,
wherein the second switch further includes a sixth terminal, and
the sixth terminal of the second switch is connected to one end of the ninth filter.

20. The radio frequency circuit according to claim 19,
wherein the radio frequency circuit has a first mode and a second mode,
in the first mode, (i) in the first switch, the first terminal of the first switch is connected to the third terminal of the first switch, and the second terminal of the first switch is connected to the fourth terminal of the first switch, and (ii) in the second switch, the first terminal of the second switch is connected to the second terminal and the sixth terminal of the second switch, and
in the second mode, (i) in the first switch, the first terminal of the first switch is connected to the fifth terminal of the first switch, and (ii) in the second switch, the first terminal of the second switch is connected to the third terminal and the sixth terminal of the second switch.
